(19) United States
(12) Patent Application Publication
(10) Pub. No.: US 2008/0025823 A1
(43) Pub. Date: Jan. 31, 2008

(54) LOAD LOCK DEVICE, AND SUBSTRATE PROCESSING APPARATUS AND SUBSTRATE PROCESSING SYSTEM INCLUDING THE SAME

(76) Inventor: Masahiko Harumoto, Kyoto-shi (JP)

Correspondence Address: OSTROLENK FABER GERB & SOFFEN, 1180 AVENUE OF THE AMERICAS, NEW YORK, NY, 100368403, US

(21) Appl. No.: 11/828,863

(22) Filed: Jul. 26, 2007

(30) Foreign Application Priority Data
Jul. 31, 2006 (JP) 2006-208764
Jul. 31, 2006 (JP) 2006-208765

(51) Int. Cl. H01L 21/677

(52) U.S. Cl. 414/217.1; 414/804; 414/939

(57) ABSTRACT

A load lock chamber includes a chamber. A vacuum pump is connected to the bottom of the chamber through a pipe. A cooling pipe is buried in the upper part of the chamber. One and the other ends of the cooling pipe are connected with a refrigerant circulator. When the pressure in the chamber is reduced, the chamber continues to be cooled during the period between when the pressure in the chamber becomes lower than a threshold and immediately before the inside of the chamber is released to atmospheric pressure.

### BACKGROUND OF THE INVENTION

1. Field of the Invention

The present invention relates to a load lock device used to carry in or take out a substrate to or from a reduced pressure processing device that carries out processing to a substrate at a pressure lower than atmospheric pressure, and a substrate processing apparatus and a substrate processing system including such a device.

2. Description of the Background Art

The substrate processing apparatus is used to carry out various types of processing to various kinds of substrates including a semiconductor substrate, a substrate for a liquid crystal display, a substrate for a plasma display, a substrate for an optical disk, a substrate for a magnetic disk, a substrate for a magneto-optical disk, and a substrate for a photomask.

Such a substrate processing apparatus generally carries out a plurality of different types of processing successively to a single substrate. The substrate processing apparatus disclosed by JP 2003-324139 A includes an indexer block, an anti-reflection film processing block, a resist film processing block, a development processing block, and an interface block. An exposure device that subjects a substrate to exposure processing is arranged adjacent to the interface block.

In the above-mentioned substrate processing apparatus, a substrate carried in the indexer block is provided with an anti-reflection film in the anti-reflection film processing block and a resist film in the resist film processing block and then transported to the exposure device through the interface block. After the resist film on the substrate is subjected to exposure processing in the exposure device, the substrate is transported to the development processing block through the interface block. The resist film on the substrate is subjected to development processing in the development processing block to have a resist pattern formed thereon, and then the substrate is transported to the indexer block.

In recent years, as the density and integration of devices increase, there has been a demand for finer resist patterns. The resolution performance of the exposure device, which is a key to obtaining finer resist patterns, depends on the wavelength of the light source of the exposure device. Exposure techniques that use EUV (extra-ultraviolet) having an extremely short wavelength of about 13 nm have been developed.

The EUV is easily absorbed by the air. Therefore, the inside of the exposure device must be kept in a state whose degree of vacuum is extremely high (hereinafter referred to as “high vacuum state”). The inside of the substrate processing apparatus is generally kept at atmospheric pressure. Therefore, in order to transport a substrate between the substrate processing apparatus and the exposure device while the inside of the exposure device is kept in a high vacuum state, a load lock chamber used to adjust the their mutual environments must be provided (see for example JP 2000-150395 A).

A substrate is temporarily stored in the load lock chamber and the load lock chamber has its pressure reduced to the level of a high vacuum state in this state when the substrate is transported from the substrate processing apparatus to the exposure device. Then, the substrate is transported from the load lock chamber in the high vacuum state to the exposure device in the high vacuum state. However, it takes long to reduce the pressure of the load lock chamber to the level of a high vacuum state, which give rise to a drop in the throughput.

### SUMMARY OF THE INVENTION

It is an object of the invention to provide a load lock device that allows the degree of vacuum to be quickly raised, and a substrate processing apparatus and a substrate processing system including the device.

(1) A load lock device according to one aspect of the invention is used to carry in or take out a substrate to or from a reduced pressure processing device that carries out processing to the substrate at a pressure lower than atmospheric pressure and includes a housing that can accommodate a substrate and forms a sealed space, pressure reducing device for reducing pressure in the housing, and cooler for cooling the housing when the pressure reducing device reduces the pressure in the housing.

In the load lock device, while a substrate is accommodated in the housing that forms a sealed space, the pressure in the housing is reduced by the pressure reducing device. When the pressure in the housing is reduced, the housing is cooled by the cooler.

The housing is cooled when the pressure in the housing is reduced, so that the motion of molecules remaining in the housing is substantially stopped in the vicinity of the surface of the housing and the molecules are made to adhere to the housing. In this way, the degree of vacuum in the housing can quickly be raised. Consequently, the substrate can quickly be carried into or taken out from the reduced pressure processing device, which can improve the throughput.

(2) The cooler may include refrigerant supplier for cooling the housing using a refrigerant.

In this way, the housing may be cooled by the refrigerant supplier using the refrigerant when the pressure in the housing is reduced, so that the motion of molecules remaining in the housing may substantially be stopped in the vicinity of the surface of the housing, and the molecules are made to adhere to the housing. Therefore, the degree of vacuum in the housing can quickly be raised.

(3) The refrigerant may be liquid or gaseous nitrogen. In this way, the temperature of the housing can sufficiently be lowered. This allows the motion of molecules in the housing to be sufficiently stopped. Therefore, the degree of vacuum in the housing can quickly be raised.

(4) The refrigerant may be liquid or gaseous helium. In this way, the temperature of the housing can greatly be lowered. This allows the motion of molecules in the housing to be surely stopped. Therefore, the degree of vacuum can surely be raised.

(5) The cooler may include a Peltier element for cooling. In this way, the housing can be cooled with a simple arrangement, and the load lock device can be reduced in size and cost.

(6) The load lock device may further include housing heater for heating the housing.

In this way, the housing is heated by the housing heater, so that a liquid adhering to the housing is evaporated. This prevents the liquid adhering to the housing from being solidified because of adiabatic expansion during the pressure reducing in the housing. Therefore, the degree of vacuum in the housing can be prevented from being lowered because of solidified substances that are gradually sublimated. Consequently, the degree of vacuum in the housing can quickly be raised.

(7) The load lock device may further include substrate heater for heating a substrate accommodated in the housing.

In this way, the substrate in the housing is heated by the substrate heater, so that a liquid adhering to the substrate is evaporated. Therefore, the liquid adhering to the substrate can be prevented from being solidified because of adiabatic expansion during the pressure reducing in the housing. Therefore, the degree of vacuum in the housing can be prevented from being lowered because of solidified substances that are gradually sublimated. Consequently, the degree of vacuum in the housing can quickly be raised.

(8) The load lock device may further include drying gas supplier for supplying a drying gas into the housing.

In this way, the drying gas supplier supplies a drying gas into the housing, so that a liquid adhering to the substrate and the housing is more easily evaporated. In addition, the vapor in the housing is replaced by the drying gas. As a result, the liquid adhering to the substrate and the housing can be prevented from being solidified because of adiabatic expansion when the pressure in the housing is reduced. Therefore, the degree of vacuum in the housing can be prevented from being lowered because of solidified substances that are gradually sublimated. Consequently, the degree of vacuum in the housing can quickly be raised.

(9) The load lock device may further include a pressure detector that detects the pressure in the housing, and a control unit that starts cooling of the housing by the cooler if the pressure detected by the pressure detector is lower than a predetermined value.

In this way, the housing is cooled while the pressure in the housing is sufficiently lowered. Therefore, the motion of molecules remaining in the housing can sufficiently be stopped in the vicinity of the surface of the housing and the molecules are made to adhere to the housing. Consequently, the degree of vacuum in the housing can quickly be raised.

(10) A substrate processing apparatus according to another aspect of the invention is provided adjacent to a reduced pressure processing device that carries out processing to a substrate at a pressure lower than atmospheric pressure and includes a normal pressure processing unit that carries out processing to a substrate at atmospheric pressure, and an interface used to receive and transfer the substrate between the normal pressure processing unit and the reduced pressure processing device, the interface includes a load lock device used to carry in or take out a substrate to or from the reduced pressure processing device, and the load lock device includes a housing that can accommodate a substrate and forms a sealed space, pressure reducing device for reducing pressure in the housing, and cooler for cooling the housing when the pressure reducing device reduces the pressure in the housing.

In the substrate processing apparatus, the normal pressure processing unit carries out processing to a substrate at atmospheric pressure, and the interface receives and transfers a substrate between the normal pressure processing unit and the reduced pressure processing device. The substrate is temporarily carried into the load lock device when the substrate is carried into or taken out from the reduced pressure processing device by the interface.

In the load lock device, while the substrate is accommodated in the housing that forms a sealed space, the pressure in the housing is reduced by the pressure reducing device. When the pressure in the housing is reduced, the housing is cooled by the cooler.

The housing is cooled when the pressure in the housing is reduced, so that the motion of molecules remaining in the housing can substantially be stopped in the vicinity of the surface of the housing, and the molecules are made to adhere to the housing. In this way, the degree of vacuum in the housing can quickly be raised. Consequently, the substrate can quickly be carried into or taken out from the reduced pressure processing device, which can improve the throughput.

(11) A substrate processing system according to yet another aspect of the invention includes a reduced pressure processing device that carries out processing to a substrate at a pressure lower than atmospheric pressure, and a load lock device used to carry in or take out a substrate to or from the reduced pressure processing device, and the load lock device includes a housing that can accommodate a substrate and forms a sealed space, pressure reducing device for reducing pressure in the housing, and cooler for cooling the housing when the pressure reducing device reduces the pressure in the housing.

In the substrate processing system, a substrate is carried into or taken out from the reduced pressure processing device through the load lock device, and the reduced pressure processing device carries out processing to the substrate at a pressure lower than atmospheric pressure.

In the load lock device, while the substrate is accommodated in the housing that forms a sealed space, the pressure in the housing is reduced by the pressure reducing device. When the pressure in the housing is reduced, the housing is cooled by the cooler.

The housing is cooled when the pressure in the housing is reduced, so that the motion of molecules remaining in the housing can substantially be stopped in the vicinity of the surface of the housing, and the molecules are made to adhere to the housing. In this way, the degree of vacuum in the housing can quickly be raised. Consequently, the substrate can quickly be carried into or taken out from the reduced pressure processing device, which can improve the throughput.

(12) The substrate processing system may further include an interface that transports a substrate to the reduced pressure processing device, and the load lock device may be provided at the interface.

In this way, the substrate is temporarily carried into the load lock device and then the substrate is transported to the reduced pressure processing device. In the load lock device, the degree of vacuum can quickly be raised. Consequently, the substrate can quickly be carried into or taken out from the reduced pressure processing device.

(13) The substrate processing system may further include a normal pressure processing unit that carries out processing to a substrate at atmospheric pressure, and the interface receives and transfers a substrate between the normal pressure processing unit and the reduced pressure processing device.

In this way, when the substrate is transported between the normal pressure processing unit and the reduced pressure processing device, the substrate is temporarily carried into the load lock device at the interface. In the load lock device, the degree of vacuum can quickly be raised. Consequently, the substrate can quickly be transported between the normal pressure processing unit and the reduced pressure processing device.

(14) A load lock device according to a further aspect of the invention is used to carry in or take out a substrate to or from a reduced pressure processing device that carries out processing to a substrate at a pressure lower than atmospheric pressure and includes a housing that can accommodate a substrate and forms a sealed space, pressure reducing device for reducing pressure in the housing, and atmosphere replacing device for replacing the atmosphere in the housing with a rare gas before the pressure reducing device reduces the pressure in the housing.

In this load lock device, a substrate is accommodated into the housing that forms a sealed space, and the atmosphere in the housing is replaced with a rare gas in the state by the atmosphere replacing device. Then, the pressure reducing device reduces the pressure in the housing.

In this way, the atmosphere in the housing is replaced by a rare gas before the pressure reduction in the housing, so that the housing can be evacuated with smaller energy than that in the case in which the atmosphere in the housing is the air. Therefore, the degree of vacuum in the housing can quickly be raised. Consequently, the substrate can quickly be carried into or taken out from the reduced pressure processing device, which can improve the throughput.

(15) The atmosphere replacing device may include rare gas supplier for supplying the rare gas into the housing.

In this way, the rare gas is supplied into the housing before the pressure in the housing is reduced, and the atmosphere in the housing is replaced by the rare gas.

(16) The atmosphere replacing device may further include cooler for liquefying or solidifying a constituent in the atmosphere in the housing excluding the rare gas.

In this way, constituents in the atmosphere excluding the rare gas may be liquefied or solidified while the rare gas is supplied into the housing, so that the atmosphere can be replaced by the rare gas efficiently and quickly.

(17) The rare gas may be helium gas. The boiling point of helium gas is lower than the boiling points of atmospheric constituents such as nitrogen, oxygen, carbon dioxide, and water vapor, and therefore while these atmospheric constituents are liquefied or solidified, the helium gas can be maintained in a gas state.

(18) The atmosphere replacing device may further include exhaust unit for exhausting the atmosphere from the housing.

In this way, the supply of the rare gas into the housing and the evacuation of the housing can be carried out simultaneously or alternately, so that the atmosphere in the housing can efficiently be replaced by the rare gas.

(19) The load lock device may further include housing heater for heating the housing.

In this way, the housing is heated by the housing heater, so that a liquid adhering to the housing is evaporated. Therefore, the liquid adhering to the housing can be prevented from being solidified because of adiabatic expansion when the pressure in the housing is reduced. Therefore, the degree of vacuum in the housing can be prevented from being lowered because of solidified substances that are gradually sublimated. Consequently, the degree of vacuum in the housing can quickly be raised.

(20) The load lock device may further include substrate heater for heating a substrate accommodated in the housing.

In this way, the substrate in the housing is heated by the substrate heater, so that a liquid adhering to the substrate is evaporated. Therefore, the liquid adhering to the housing can be prevented from being solidified because of adiabatic expansion when the pressure in the housing is reduced. Therefore, the degree of vacuum in the housing can be prevented from being lowered because of solidified substances that are gradually sublimated. Consequently, the degree of vacuum in the housing can quickly be raised.

(21) The load lock device may further include housing cooler for cooling the housing when the pressure reducing device reduces the pressure in the housing.

In this way, the housing is cooled by the cooler when the pressure in the housing is reduced, so that the motion of molecules remaining in the housing is substantially stopped in the vicinity of the surface of the housing and the molecules are made to adhere to the housing. In this way, the degree of vacuum in the housing can more quickly be raised.

(22) A substrate processing apparatus according to a further aspect of the invention is provided adjacent to a reduced pressure processing device that carries out processing to a substrate at a pressure lower than atmospheric pressure and includes a normal pressure processing unit that carries out processing to the substrate at atmospheric pressure, and an interface used to receive and transfer a substrate between the normal pressure processing unit and the reduced pressure processing device, the interface includes a load lock device used to carry in or take out a substrate to or from the reduced pressure processing device, and the load lock device includes a housing that can accommodate a substrate and forms a sealed space, pressure reducing device for reducing pressure in the housing, and atmosphere replacing device for replacing the atmosphere in the housing with a rare gas before the pressure reducing device reduces the pressure in the housing.

In the substrate processing apparatus, the normal pressure processing unit carries out processing to a substrate at atmospheric pressure, and the interface receives and transfers the substrate between the normal pressure processing unit and the reduced pressure processing device. The substrate is temporarily carried into the load lock device when the substrate is carried into or taken out from the reduced pressure processing device by the interface.

In the load lock device, the substrate is accommodated in the housing that forms a sealed space, and the atmosphere in the housing is replaced with a rare gas by the atmosphere replacing device in the state. Then, the pressure reducing device reduces the pressure in the housing.

The atmosphere in the housing is replaced by a rare gas before the pressure in the housing is reduced, so that the housing can be evacuated with smaller energy than that in the case in which the atmosphere in the housing is the air. Therefore, the degree of vacuum can quickly be raised. Consequently, the substrate can quickly be carried into or taken out from the reduced pressure processing device, which can improve the throughput.

(23) A substrate processing system according to an additional aspect of the invention includes a reduced pressure processing device that carries out processing to a substrate at a pressure lower than atmospheric pressure, and a load lock device used to carry in or take out a substrate to or from the reduced pressure processing device, the load lock device includes a housing that can accommodate a substrate and forms a sealed space, pressure reducing device for reducing the pressure in the housing, and atmosphere replacing device for replacing the atmosphere in the housing with a rare gas before the pressure reducing device reduces the pressure in the housing.

In the substrate processing system, the substrate is carried into or taken out from the reduced pressure processing device through the load lock device, and the reduced pressure processing device carries out processing to the substrate at a pressure lower than atmospheric pressure.

In the load lock device, the substrate is accommodated in the housing that forms a sealed space, and the atmosphere in the housing is replaced with a rare gas by the atmosphere replacing device in the state. Then, the pressure reducing device reduces the pressure in the housing.

The atmosphere in the housing is replaced by a rare gas before the pressure in the housing is reduced, so that the housing can be evacuated with smaller energy than that in the case in which the atmosphere in the housing is the air. Therefore, the degree of vacuum can quickly be raised. Consequently, the substrate can quickly be carried into or taken out from the reduced pressure processing device, which can improve the throughput.

(24) The substrate processing system may further include an interface that transports a substrate to the reduced pressure processing device, and the load lock device may be provided at the interface.

In this way, the substrate is temporarily carried into the load lock device at the interface and then the substrate is transported to the reduced pressure processing device. The degree of vacuum can quickly be raised in the load lock device. Therefore, the substrate can quickly be carried into or taken out from the reduced pressure processing device.

(25) The substrate processing system may further include a normal pressure processing unit that carries out processing to a substrate at atmospheric pressure, and the interface may receive and transfer the substrate between the normal pressure processing unit and the reduced pressure processing device.

In this way, when the substrate is transported between the normal pressure processing unit and the reduced pressure processing device, the substrate is temporarily carried into the load lock device at the interface. The degree of vacuum can quickly be raised in the load lock device. Therefore, the substrate can quickly be transported between the normal pressure processing unit and the reduced pressure processing device.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a plan view of a substrate processing apparatus including a pressure reducing device according to a first embodiment of the invention;

FIG. 2 is a schematic side view of the substrate processing apparatus shown in FIG. 1 viewed from the +X direction;

FIG. 3 is a schematic side view of the substrate processing apparatus shown in FIG. 1 viewed from the −X direction;

FIG. 4 is a schematic sectional view of a load lock chamber in an XY plane;

FIG. 5 is a schematic sectional view of the load lock chamber in a YZ plane;

FIG. 6 is diagram showing a control system for the load lock chamber;

FIGS. 7 and 8 are flowcharts for use in illustrating the operation of the load lock chamber;

FIG. 9 is a view of a first modification of the load lock chamber;

FIG. 10 is a view of a second modification of the load lock chamber;

FIG. 11 is a schematic sectional view of a load lock chamber according to a second embodiment of the invention;

FIG. 12 is a diagram showing a control system for the load lock chamber;

FIGS. 13 to 15 are flowcharts for use in illustrating the operation of the load lock chamber; and

FIG. 16 is a view of a modification of the load lock chamber.

### DESCRIPTION OF THE PREFERRED EMBODIMENTS

Now, load lock devices according to embodiments of the invention and a substrate processing apparatus and a substrate processing system including such a device will be described in conjunction with the accompanying drawings. In the following paragraphs, the substrate refers to a substrate such as a semiconductor substrate, a substrate for a liquid crystal display, a substrate for a plasma display, a glass substrate for a photomask, a substrate for an optical disk, a substrate for a magnetic disk, a substrate for a magneto-optical disk, and a substrate for a photomask.

### (A) First Embodiment

### (1) Configuration of Substrate Processing Apparatus

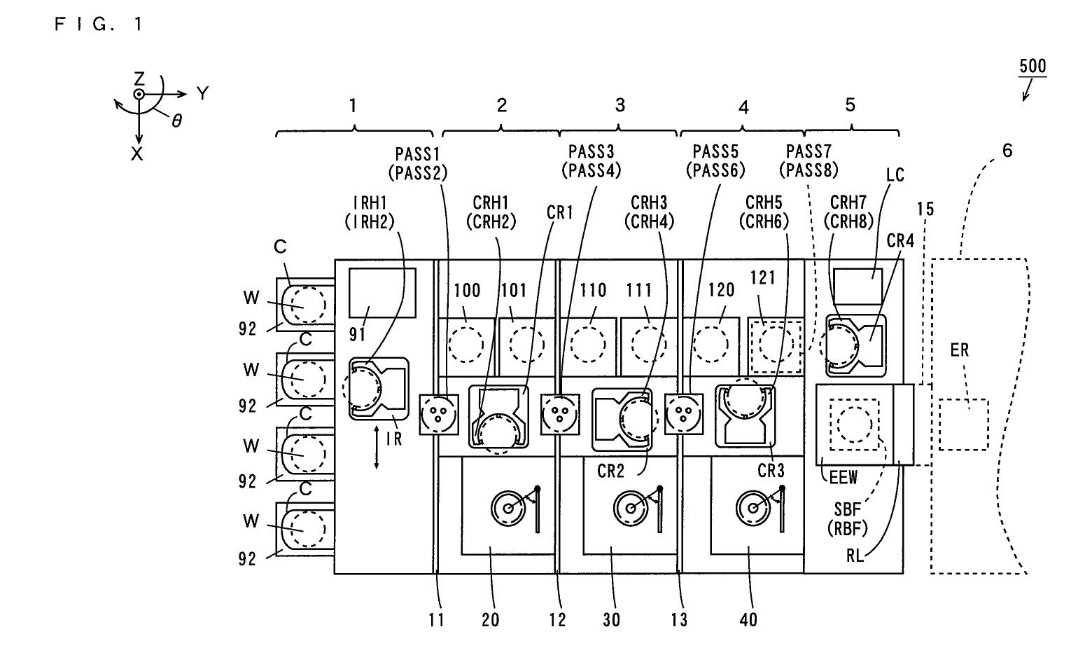

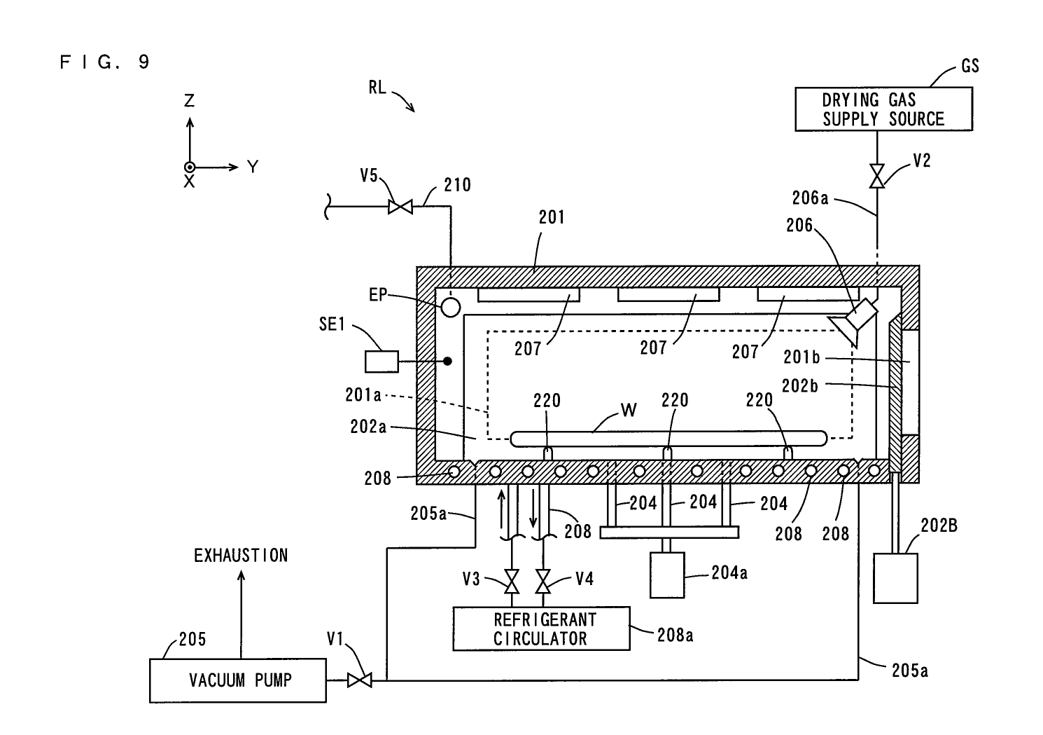

FIG. 1 is a plan view of a substrate processing apparatus according to a first embodiment of the invention. Note that FIG. 1 and FIGS. 2 to 5, FIGS. 9 to 11, and FIG. 16 that will be referred to later in the following description are accompanied by arrows that respectively indicate X, Y, and Z directions perpendicular to one another for the clarity of positional relationship. The X and Y directions are perpendicular to each other within a horizontal plane, and the Z direction corresponds to the vertical direction. In each of the directions, the direction of the arrow is defined as a +direction, and the opposite direction is defined as a −direction. A rotation direction around the Z direction is defined as a θ direction.

As shown in FIG. 1, the substrate processing apparatus 500 includes an indexer block 1, an anti-reflection film processing block 2, a resist film processing block 3, a development processing block 4, and an interface block 5. An exposure device 6 is provided adjacent to the interface block 5.

Hereinafter, the indexer block 1, the anti-reflection film processing block 2, the resist film processing block 3, the development processing block 4, and the interface block 5 will be referred to as processing blocks.

According to the embodiment, a substrate W is subjected to various kinds of processing at atmospheric pressure in each of the processing blocks in the substrate processing apparatus 500. Meanwhile, the substrate W is subjected to exposure processing in a high vacuum state (for example at 10⁻⁶ Pa) in the exposure device 6.

The indexer block 1 includes a main controller (control unit) 91 that controls the operation of the processing blocks, a plurality of carrier platforms 92, and an indexer robot IR. The indexer robot IR is provided with hands IRH1 and IRH2 one above the other to receive and transfer the substrate W.

The anti-reflection film processing block 2 includes thermal processing groups 100 and 101 for anti-reflection film, a coating processing group 20 for anti-reflection film, and a first central robot CR1. The coating processing group 20 is provided opposed to the thermal processing groups 100 and 101 with the first central robot CR1 interposed therebetween. The first central robot CR1 is provided with hands CRH1 and CRH2 one above the other to receive and transfer the substrate W.

A partition wall 11 for shielding the atmosphere is provided between the indexer block 1 and the anti-reflection processing block 2. The partition wall 11 is provided with substrate platforms PASS1 and PASS2 one above the other in a close proximity that are used to receive and transfer the substrate W between the indexer block 1 and the anti-reflection film processing block 2. The upper substrate platform PASS1 is used to transport the substrate W from the indexer block 1 to the anti-reflection film processing block 2. The lower substrate platform PASS2 is used to transport the substrate W from the anti-reflection film processing block 2 to the indexer block 1.

The substrate platforms PASS1 and PASS2 are each provided with an optical sensor (not shown) that detects the presence or absence of the substrate W. In this way, whether or not the substrate W is placed on the substrate platform PASS1 or PASS2 can be determined. In addition, the substrate platforms PASS1 and PASS2 each have a plurality of support pins secured thereto. Note that substrate platforms PASS3 to PASS8 that will be described later are each similarly provided with an optical sensor and support pins.

The resist film processing block 3 includes thermal processing groups 110 and 111 for resist film, a coating processing group 30 for resist film, and a second central robot CR2. The coating processing group 30 is provided opposed to thermal processing groups 110 and 111 with the second central robot CR2 interposed therebetween. The second central robot CR2 has hands CRH3 and CRH4 provided one above the other used to receive and transfer the substrate W.

An atmosphere shielding partition wall 12 is provided between the anti-reflection film processing block 2 and the resist film processing block 3. The partition wall 12 is provided with the substrate platforms PASS3 and PASS4 one above the other in a close proximity that are used to receive and transfer the substrate W between the anti-reflection film processing block 2 and the resist film processing block 3. The upper substrate platform PASS3 is used to transport the substrates W from the anti-reflection film processing block 2 to the resist film processing block 3, and the lower substrate platform PASS4 is used to transport the substrates W from the resist film processing block 3 to the anti-reflection film processing block 2.

The development processing block 4 includes a thermal processing group 120 for development, a thermal processing group 121 for post-exposure bake, a development processing group 40, and a third central robot CR3. The thermal processing group 121 is provided adjacent to the interface block 5 and includes the substrate platforms PASS7 and PASS8 as will be described. The development processing group 40 is provided opposed to the thermal processing group 120 and the thermal processing group 121 with the third central robot CR3 interposed therebetween. The third central robot CR3 has hands CRH5 and CRH6 provided one above the other used to receive and transfer the substrates W.

An atmosphere shielding partition wall 13 is provided between the resist film processing block 3 and the development processing block 4. The partition wall 13 has the substrate platforms PASS5 and PASS6 provided one above the other in a close proximity that receive and transfer the substrate W between the resist film processing block 3 and the development processing block 4. The upper substrate platform PASS5 is used to transport the substrate W from the resist film processing block 3 to the development processing block 4 and the lower substrate platform PASS6 is used to transport the substrate W from the development processing block 4 to the resist film processing block 3.

The interface block 5 includes a fourth central robot CR4 and an edge exposure unit EEW. A sending buffer unit SBF, a return buffer unit RBF, and a load lock chamber RL are provided under the edge exposure unit EEW. Details of the load lock chamber RL will be described later. The fourth central robot CR4 has hands CRH7 and CRH8 provided one above the other that receive and transfer the substrate W.

The interface block 5 includes a local controller LC that controls the operation of elements in the interface block 5.

The exposure device 6 is connected to the load lock chamber RL through a coupling portion 15. A transport mechanism ER is provided in the exposure device 6.

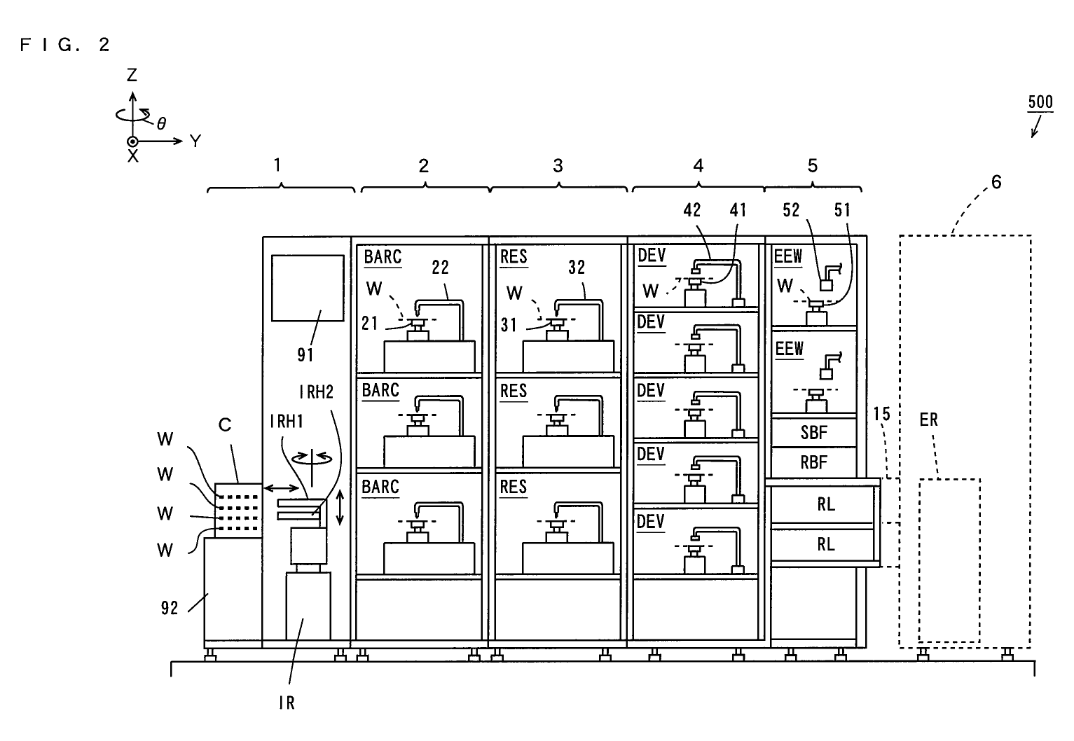

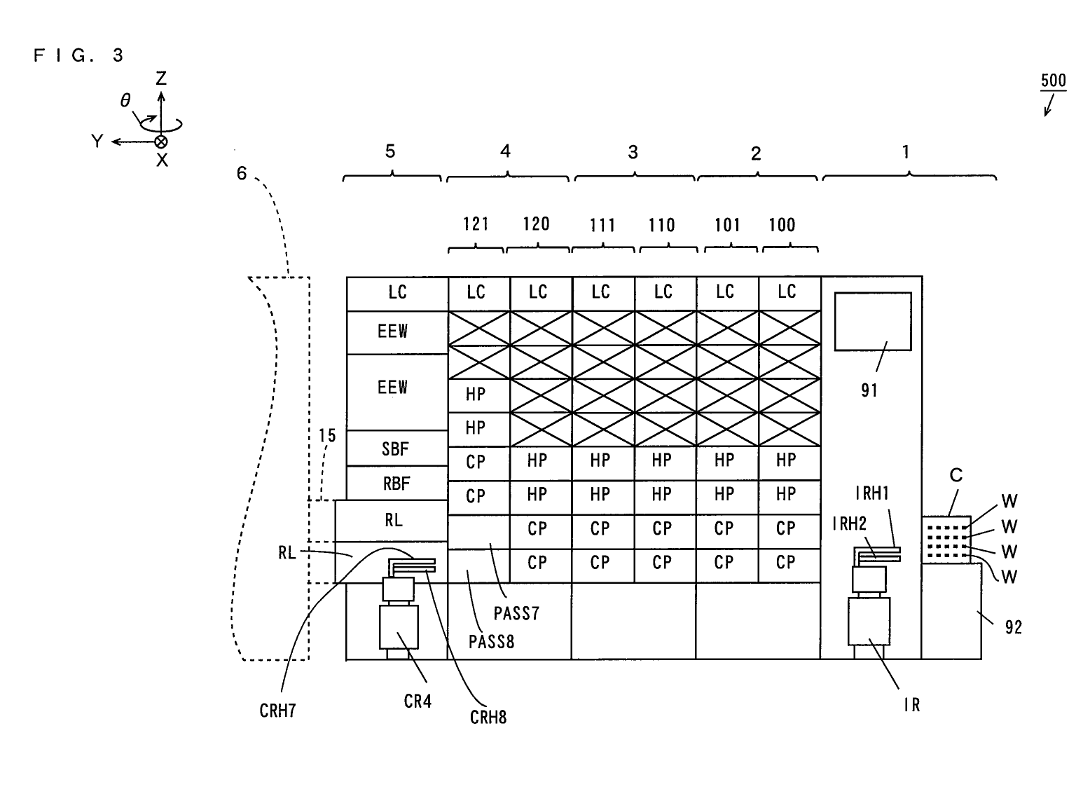

FIG. 2 is a schematic side view of the substrate processing apparatus 500 shown in FIG. 1 as viewed from the +X direction, and FIG. 3 is a schematic side view of the substrate processing apparatus 500 shown in FIG. 1 as viewed from the −X direction.

With reference to FIG. 2, the configuration of the substrate processing apparatus 500 on the +X side will be described. As shown in FIG. 2, the coating processing group 20 (see FIG. 1) in the anti-reflection film processing block 2 has a vertical stack of three coating units BARC. The coating units BARC each include a spin chuck 21 that rotates as it holds the substrate W in a horizontal position by suction, and a supply nozzle 22 that supplies a coating liquid for an anti-reflection film to the substrate W held on the spin chuck 21.

The coating processing group 30 (see FIG. 1) in the resist film processing block 3 has a vertical stack of three coating units RES. The coating units RES each include a spin chuck 31 that rotates as it holds the substrate W in a horizontal position by suction and a supply nozzle 32 that supplies a coating liquid for a resist film to the substrate W held on the spin chuck 31.

The development processing group 40 in the development processing block 4 has a vertical stack of five development processing units DEV. The development processing units DEV each include a spin chuck 41 that rotates as it holds the substrate W in a horizontal position by suction and a supply nozzle 42 that supplies a development liquid to the substrate W held on the spin chuck 41.

The interface block 5 has a vertical stack of two edge exposure units EEW, a sending buffer unit SBF, a return buffer unit RBF, and two load lock chambers RL. The edge exposure units EEW each include a spin chuck 51 that rotates as it holds the substrate W in a horizontal position by suction and a light irradiator 52 that exposes the peripheral edge of the substrate W held on the spin chuck 51 to light. The load lock chamber RL will be described later.

Now, with reference to FIG. 3, the configuration of the substrate processing apparatus 500 on the -X side will be described. As shown in FIG. 3, the thermal processing groups 100 and 101 in the anti-reflection film processing block 2 each have a stack of two heating units (hot plates) HP and two cooling units (cooling plates) CP. The thermal processing groups 100 and 101 each have a local controller LC provided in the uppermost part to control the temperatures of the heating units HP and the cooling units CP.

In the resist film processing block 3, the thermal processing groups 110 and 111 each have a stack of two heating units HP and two cooling units CP. The thermal processing groups 110 and 111 each also have a local controller LC provided in the uppermost part to control the temperatures of the heating units HP and the cooling units CP.

In the development processing block 4, the thermal processing group 120 has a stack of two heating units HP and two cooling units CP. The thermal processing group 121 has a vertical stack of two heating units HP, two cooling units CP, and the substrate platforms PASS7 and PASS8. The thermal processing group 120 and the thermal processing group 121 each have a local controller LC provided in the uppermost part to control the temperatures of the heating units HP and the cooling units CP.

Note that the number of the coating units BARC and RES, the development processing units DEV, the edge exposure units EEW, the heating units HP, the cooling units CP, and the load lock chambers RL may be changed as required depending on the processing speed of each of the blocks.

### (2) Operation of Substrate Processing Apparatus

Now, the operation of the substrate processing apparatus 500 according to the embodiment will be described in conjunction with FIGS. 1 to 3.

Carriers C that store a plurality of substrates W in multiple stages are carried onto the carrier platforms 92 in the indexer block 1. The indexer robot IR takes out an unprocessed substrate W stored in the carrier C using the hand IRH1. Thereafter, the indexer robot IR rotates in the ±θ direction while moving in the ±X direction and places the unprocessed substrate W on the substrate platform PASS1.

Although FOUPs (Front Opening Unified Pods) are used as the carriers C in the embodiment, the present invention is not limited to the arrangement and SMIF (Standard Mechanical Inter Face) pods, or OCs (Open Cassettes) that expose the stored substrates W to the outside air may be used.

Furthermore, although the linear-type transport robots that move their hands forward or backward by linearly sliding them to the substrate W are used as the indexer robot IR, and the first to fourth central robots CR1 to CR4, the present invention is not limited to the use of the robots of this type and for example multi-joint type transport robots that linearly move their hands forward and backward by moving their joints may be used.

The unprocessed substrate W placed on the substrate platform PASS1 is received by the first central robot CR1 in the anti-reflection film processing block 2. The first central robot CR1 carries the substrate W into the thermal processing groups 100 and 101.

Thereafter, the first central robot CR1 then takes out the thermally processed substrate W from the thermal processing groups 100 and 101 and carries the substrate W into the coating processing group 20. In the coating processing group 20, the substrate W is coated with an anti-reflection film using the coating unit BARC in order to reduce standing waves and halation generated during the exposure processing.

Then, the first central robot CR1 takes out the coated substrate W from the coating processing group 20 and carries the substrate W into the thermal processing group 100 or 101. The first central robot CR1 takes out the thermally processed substrate W from the thermal processing group 100 or 101 and places the substrate W on the substrate platform PASS3.

The substrate W placed on the substrate platform PASS3 is received by the second central robot CR2 in the resist film processing block 3. The second central robot CR2 carries the substrate W into the thermal processing group 110 or 111.

Thereafter, the second central robot CR2 takes out the thermally processed substrate W from the thermal processing group 110 or 111 and carries the substrate W into the coating processing group 30. In the coating processing group 30, the substrate W coated with the anti-reflection film is coated with a resist film by the coating unit RES.

Then, the second central robot CR2 takes out the coated substrate W from the coating processing group 30 and carries the substrate W into the thermal processing group 110 or 111. Thereafter, the second central robot CR2 takes out the thermally processed substrate W from the thermal processing unit 110 or 111 and places the substrate W on the substrate platform PASS5.

The substrate W placed on the substrate platform PASS5 is received by the third central robot CR3 in the development processing block 4. The third central robot CR3 places the substrate W on the substrate platform PASS7.

The substrate W placed on the substrate platform PASS7 is received by the fourth central robot CR4 in the interface block 5. The fourth central robot CR4 carries the substrate W into the edge exposure unit EEW. In the edge exposure unit EEW, the peripheral edge of the substrate W is subjected to exposure processing.

Then, the fourth central robot CR4 takes out the edge-exposed substrate W from the edge exposure unit EEW and carries the substrate W into the load lock chamber RL.

The load lock chamber RL has its pressure reduced until it attains a high vacuum state. Then, the substrate W is carried into the exposure device 6 from the load lock chamber RL by the transport mechanism ER provided in the exposure device 6. Note that the load lock chamber RL is temporarily kept in the high vacuum state.

Then, the substrate W after the exposure processing is carried into the load lock chamber RL kept in the high vacuum state by the transport mechanism ER. Then, the load lock chamber RL is released to atmospheric pressure, and the substrate W after the exposure processing is taken out from the load lock chamber RL by the fourth central robot CR4.

Note that when the substrate W is carried into the exposure device 6 as described above, the load lock chamber RL is temporarily kept in a high vacuum state. Therefore, during the period, the load lock chamber RL cannot receive the substrate W from the fourth central robot CR4.

If all the load lock chambers RL (two in the embodiment) are not able to receive the substrate W, the edge-exposed substrate W is temporarily stored in the sending buffer unit SBF by the fourth central robot CR4.

Thereafter, the fourth central robot CR4 carries the substrate W after the exposure processing taken out from the load lock chamber RL into the thermal processing group 121 in the development processing block 4. In the thermal processing group 121, the substrate W is subjected to post-exposure bake (PEB).

Note that when the development processing block 4 cannot receive the substrate W after the exposure processing because of a failure or the like, the substrate W after the exposure processing can temporarily be stored in the return buffer unit RBF in the interface block 5.

Then, the fourth central robot CR4 takes out the substrate W from the thermal processing group 121 and places the substrate W on the substrate platform PASS8.

The substrate W placed on the substrate platform PASS8 is received by the third central robot CR3 in the development processing block 4. The third central robot CR3 carries the substrate W into the development processing group 40. In the development processing group 40, the substrate W after the exposure processing is subjected to development processing.

Then, the third central robot CR3 takes out the substrate W after the development processing from the development processing group 40 and carries the substrate W into the thermal processing group 120. Then, the third central robot CR3 takes out the thermally processed substrate W from the development thermal processing group 120 and places the substrate W on the substrate platform PASS6.

The substrate W placed on the substrate platform PASS6 is placed on the substrate platform PASS4 by the second central robot CR2 in the resist film processing block 3. The substrate W placed on the substrate platform PASS4 is placed on the substrate platform PASS2 by the first central robot CR1 in the anti-reflection film processing block 2.

The substrate W placed on the substrate platform PASS2 is stored in the carrier C by the indexer robot IR in the indexer block 1. In this way, the various kinds of processing to the substrate W in the substrate processing apparatus 500 end.

### (3) Details of Load Lock Chamber

As described above, when the substrate W is transported from the substrate processing apparatus 500 to the exposure device 6, the substrate W is temporarily carried into the load lock chamber RL in the interface block 5. When the pressure of the load lock chamber RL is reduced from atmospheric pressure to that of a high vacuum state, the substrate W is transported from the load lock chamber RL to the exposure device 6.

When the substrate W is transported from the exposure device 6 to the substrate processing apparatus 500, the substrate W is carried into the load lock chamber RL in the high vacuum state from the exposure device 6 and then the substrate W in the load lock chamber RL is carried into the development processing group 40.

In this way, the substrate W is transported to the exposure device 6 through the load lock chamber RL, the substrate W can be transported while the inside of the exposure device 6 can be kept in a high vacuum state. Now, the load lock chamber RL will be described in detail.

(3-1) Configuration of Load Lock Chamber

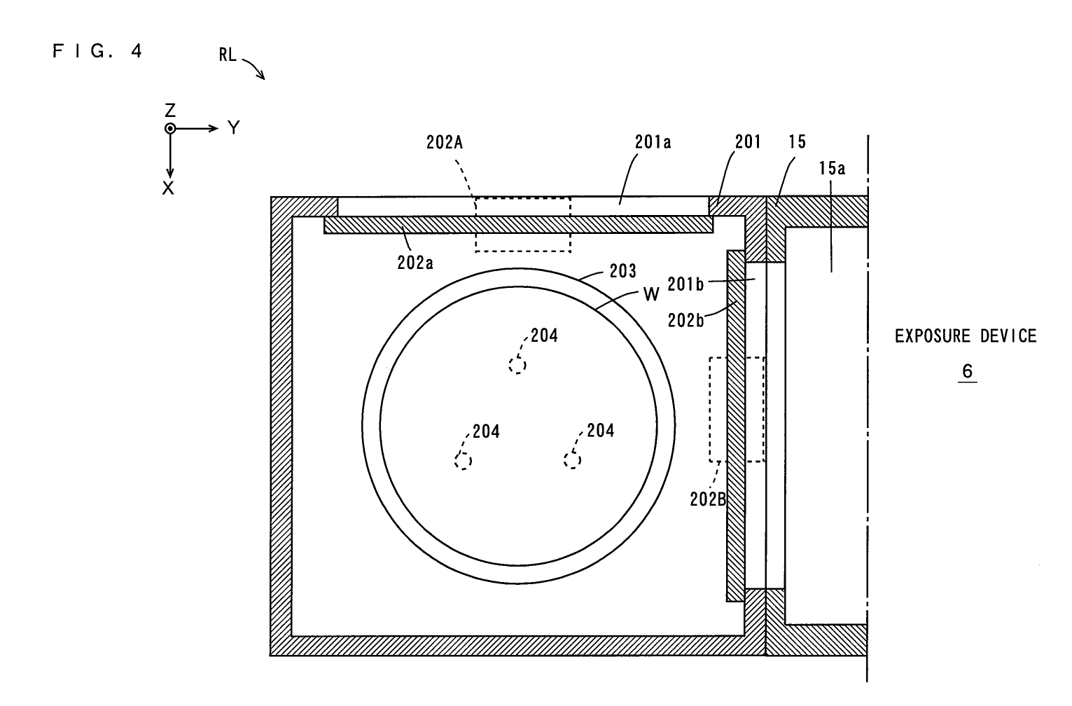

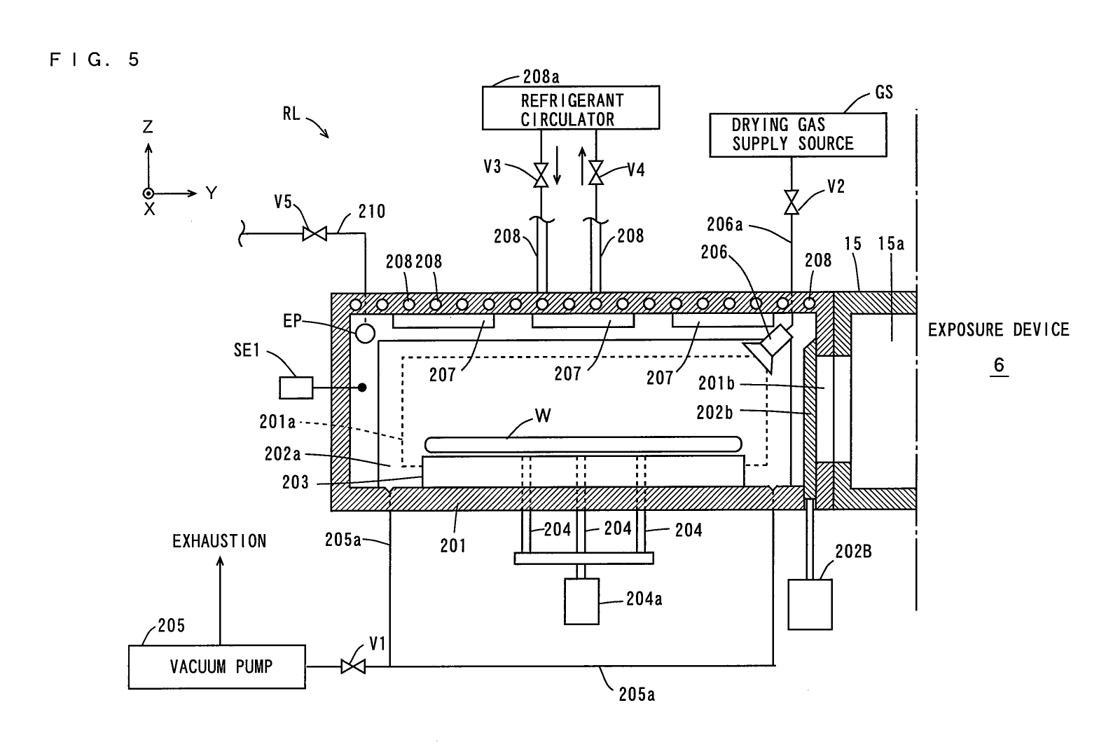

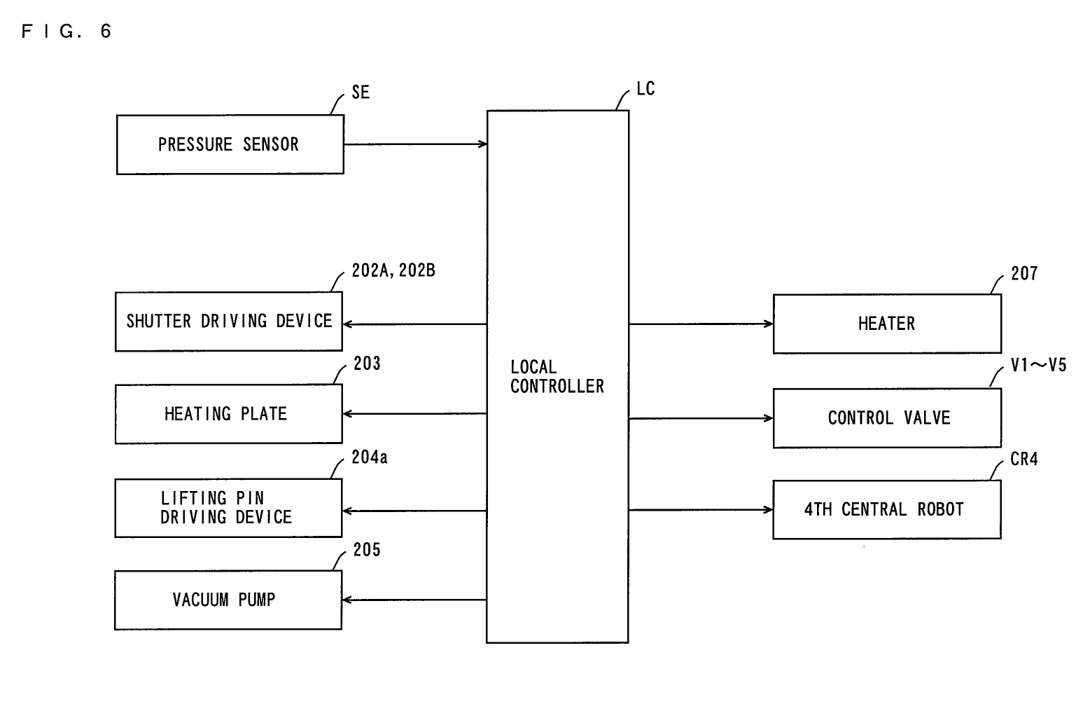

With reference to FIGS. 4 to 6, the configuration of the load lock chamber RL will be described. FIG. 4 is a schematic sectional view of the load lock chamber RL in an XY-plane, and FIG. 5 is a schematic sectional view of the load lock chamber RL in a YZ-plane. FIG. 6 is a diagram showing a control system for the load lock chamber RL.

As shown in FIG. 4, the load lock chamber RL includes a chamber 201. A first inlet/outlet 201a is provided on the side surface of the chamber 201 on the −X side and a second inlet/outlet 201b is provided on the side surface on the +Y side of the chamber 201.

The exposure device 6 is connected to the +Y side of the chamber 201 through a coupling portion 15. A coupling path 15a in communication with the inside of the exposure device 6 is formed in the coupling portion 15. The space inside the chamber 201 is in communication with the inside of the exposure device 6 through the second inlet/outlet 201b and the coupling path 15a.

Note that in FIGS. 4 and 5, one coupling path 15a is in communication with the chamber 201 of one load lock chamber RL, while a common coupling path may be provided for the chambers 201 of all the load lock chambers RL (two in the embodiment).

In the load lock chamber RL, a shutter 202a is provided to block the first inlet/outlet 201a of the chamber 201 from the inside. A shutter 202b is provided to block the second inlet/outlet 201b of the chamber 201 from the inside. The shutters 202a and 202b are moved up and down by shutter driving devices 202A and 202B, respectively, so that the first and second inlet/outlets 201a and 201b are opened/closed. When the first and second inlet/outlets 201a and 201b are closed, the inside of the chamber 201 is in an airtight state.

As shown in FIG. 5, a heating plate 203 used to heat the substrate W is provided at the bottom of the chamber 201. A plurality of lifting pins 204 are provided through the heating plate 203 and the bottom of the chamber 201. The plurality of lifting pins 204 are moved up and down by an lifting pin driving device 204a.

A vacuum pump 205 is connected to the bottom of the chamber 201 through a pipe 205a. A control valve V1 is inserted in the pipe 205a. The vacuum pump 205 operates while the control valve V1 is opened, so that the chamber 201 is evacuated. In this way, the pressure inside the chamber 201 is reduced. Note that when the vacuum pump 205 is stopped after the pressure of the chamber 201 is reduced, the control valve V1 is closed in order to prevent the air from coming into the chamber 201.

A drying gas supply nozzle 206 is provided above the heating plate 203. The drying gas supply nozzle 206 is connected with a drying gas supply source GS through a pipe 206a. A control valve V2 is inserted in the pipe 206a. The control valve V2 is opened, so that a drying gas from the drying gas supply source GS is guided through the pipe 206a to the drying gas supply nozzle 206 and supplied into the chamber 201. The drying gas may be the air with a humidity of zero, nitrogen gas or the like.

A plurality of heaters 207 used to heat the chamber 201 are provided in the upper part in the chamber 201. A cooling pipe 208 is buried in the upper part of the chamber 201. One and the other ends of the cooling pipe 208 are connected to a refrigerant circulator 208a. Control valves V3 and V4 are inserted in the cooling pipe 208.

The control valves V3 and V4 are opened, so that a refrigerant is circulated in the cooling pipe 208 by the refrigerant circulator 208a. In this way, the chamber 201 is cooled. Examples of the refrigerant may include cooling water, liquid nitrogen, liquid helium, nitrogen gas, and helium gas. According to the embodiment, the liquid helium is used as the refrigerant.

At the side of the chamber 201, an exhaust port EP is provided. The exhaust port EP is connected with an exhaust pipe 210 that extends to externally provided exhaust equipment. A control valve V5 is inserted in the exhaust pipe 210. The chamber 201 is evacuated inside by opening the control valve V5.

The chamber 201 is provided with a pressure sensor SE1 that detects pressure in the chamber 201.

Now, the control system for the load lock chamber RL will be described. FIG. 6 is a block diagram for use in illustrating the control system for the load lock chamber RL.

As shown in FIG. 6, the pressure sensor SE1 outputs a detection value for the pressure in the chamber 201 to the local controller LC (see FIG. 1) in the interface block 5. The local controller LC in the interface block 5 outputs a control signal to each of the shutter driving devices 202A and 202B, the heating plate 203, the lifting pin driving device 204a, the vacuum pump 205, the heater 207, the control valves V1 to V5, and the fourth central robot CR4 and controls the operation of these elements.

(3-2) Operation of Load Lock Chamber

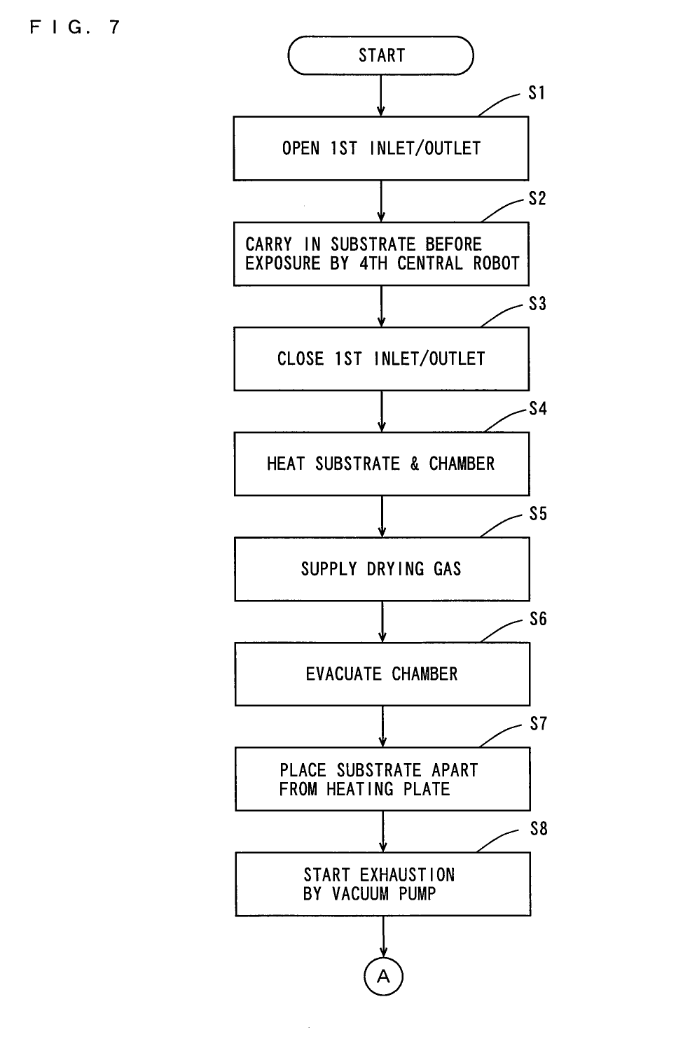

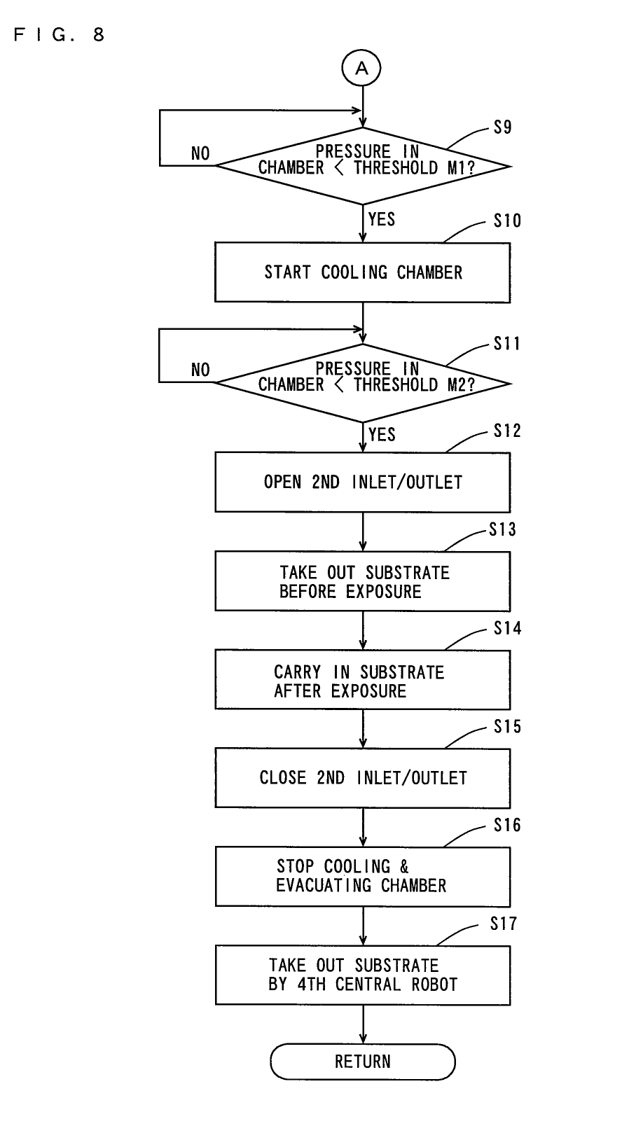

Now, with reference to FIGS. 4 to 8, the operation of the load lock chamber RL will be described. FIGS. 7 and 8 are flowcharts for use in illustrating the operation of the load lock chamber RL.

The local controller LC has the shutter 202a lowered by the shutter driving device 202A to open the first inlet/outlet 201a (step S1). Then, the local controller LC has the lifting pins 204 raised by the lifting pin driving device 204a and has the substrate W before exposure processing carried into the load lock chamber RL by the fourth central robot CR4 (FIG. 1) Then, the substrate W is placed on the lifting pins 204.

Then, the local controller LC has the lifting pins 204 lowered by the lifting pin driving device 204a to place the substrate W on the heating plate 203 and has the shutter 202a raised by the shutter driving device 202A to close the first inlet/outlet 201a (step S3).

Then, the local controller LC has the substrate W heated by the heating plate 203 and has the chamber 201 heated by the heaters 207 (step S4). In this way, moisture adhering to the substrate W and the chamber 201 is evaporated. An organic solvent remaining in organic films (the anti-reflection film and the resist film) on the substrate W and an organic solvent adhering to the chamber 201 are evaporated.

The local controller LC has the control valve V2 opened to supply a drying gas into the chamber 201 from the drying gas supply nozzle 206 (step S5). The chamber 201 is evacuated by opening the control valve V5 (step S6). In this way, the evaporated moisture and organic solvent are replaced by the drying gas.

The local controller LC then stops the heating of the substrate W and the heating of the chamber 201 and has the control valves V2 and V5 closed to stop the supply of the drying gas and the exhaustion.

Thereafter, the local controller LC has the lifting pins 204 raised by the lifting pin driving device 204a, so that the substrate W is placed apart from the heating plate 203 (step S7) and has the evacuation of the chamber 201 started by the vacuum pump 205 (step S8). In this case, as the substrate W is placed apart from the heat source, the temperature of the substrate W can be lowered. The ventilation between the substrate W and the heating plate 203 is secured, and therefore moisture if any remaining between the substrate W and the heating plate 203 can surely be removed during the evacuation of the chamber 201.

The local controller LC then determines whether or not the pressure inside the chamber 201 is lower than a predetermined threshold M1 (such as 10⁻3 Pa) based on a detection value from the pressure sensor SE1 (step S9).

If the pressure inside the chamber 201 is not less than the threshold M1, the local controller LC repeats the determination in step S9. If the pressure in the chamber 201 is lower than the threshold M1, the local controller LC opens the control valves V3 and V4 to circulate liquid helium into the cooling pipe 208, so that the chamber 201 starts to be cooled (step S10).

In this case, the pressure inside the chamber 201 is lower than the threshold M1 (10⁻³ Pa), so that there is almost no airflow in the chamber 201. Therefore, molecules remaining in the chamber 201 make almost nothing but thermal motion.

The chamber 201 is cooled in the state, and therefore the energy of the thermal motion of the molecules is reduced in the vicinity of the surface of the chamber 201. Therefore, the motion of the molecules almost stops and the molecules adhere to the inner wall of the chamber 201. Consequently, the degree of vacuum in the chamber 201 can quickly be raised.

According to the embodiment in particular, liquid helium is used as the refrigerant and therefore the temperature of the chamber 201 can sufficiently be lowered. In this way, the motion of the molecules can sufficiently be stopped. Therefore, the degree of vacuum in the chamber 201 can surely be raised.

The local controller LC then determines whether or not the pressure in the chamber 201 is lower than a predetermined threshold M2 (such as 10⁻⁶ Pa) based on a detection value from the pressure sensor SE1 (step S11).

If the pressure in the chamber 201 is not less than the threshold M2, the local controller LC repeats the determination in step S11. If the pressure in the chamber 201 is lower than the threshold M2, the local controller LC has the shutter 202b lowered to open the second inlet/outlet 201b (step S12).

In the state, the substrate W on the lifting pins 204 is taken out from the load lock chamber RL by the transport mechanism ER (FIG. 1) in the exposure device 6 (step S13). Then, the substrate W after the exposure processing is carried into the load lock chamber RL from the exposure device 6 by the transport mechanism ER and placed on the lifting pins 204 (step S14).

The local controller LC then has the shutter 202b raised by the shutter driving device 202B to close the second inlet/outlet 201b (step S15). Then, the control valves V3 and V4 are closed to stop cooling the chamber 201 and the evacuation of the chamber 201 by the vacuum pump 205 is stopped (step S16). Thereafter, the local controller LC has the shutter 202a lowered by the shutter driving device 202A to open the first inlet/outlet 201a. In this way, the chamber 201 is released to atmospheric pressure. In this state, the substrate W after the exposure processing is taken out from the load lock chamber RL by the fourth central robot CR4 (step S17). Then, in the load lock chamber RL, the operation from steps S1 to S17 is repeated.

### (4) Effect of First Embodiment

According to the embodiment, when the pressure inside the chamber 201 is reduced, the chamber 201 continues to be cooled during the period between when the pressure in the chamber 201 becomes lower than a threshold and immediately before the chamber 201 is released to atmospheric pressure.

In this way, the motion of molecules remaining in the chamber 201 is almost stopped in the vicinity of the surface of the chamber 201 and the molecules can be made to adhere to the inner wall of the chamber 201. In this way, the degree of vacuum in the chamber 201 can quickly be raised. Consequently, the substrate W can quickly be transported between the substrate processing apparatus 500 and the exposure device 6, so that the throughput can be improved.

According to the embodiment, before the pressure in the chamber 201 is reduced, the substrate W is heated by the heating plate 203 and moisture adhering to the substrate W and an organic solvent in the organic films on the substrate W are evaporated.

In this way, when the pressure in the chamber 201 is reduced, the moisture and the organic solvent adhering to the substrate W can be prevented from being solidified by adiabatic expansion. Therefore, the solidified moisture and organic solvent can be prevented from being gradually sublimated to lower the degree of vacuum inside the chamber 201. Consequently, the degree of vacuum in the chamber 201 can quickly be raised.

According to the embodiment, before the pressure in the chamber 201 is reduced, the chamber 201 is heated by the heaters 207, and the moisture and organic solvent adhering to the chamber 201 are evaporated.

In this way, during the reduction of the pressure in the chamber 201, the moisture and organic solvent adhering to the chamber 201 can be prevented from being solidified by adiabatic expansion. Therefore, the solidified moisture and organic solvent can be prevented from being gradually sublimated to lower the degree of vacuum inside the chamber 201. Consequently, the degree of vacuum in the chamber 201 can quickly be raised.

Furthermore, according to the embodiment, after the substrate W and the chamber 201 are heated, the evaporated moisture and organic solvent are replaced by a drying gas. In this way, during the reduction of the pressure in the chamber 201, the moisture and the organic solvent remaining in the organic films can surely be prevented from being solidified to lower the degree of vacuum.

### (5) Modifications of Load Lock Chamber

Now, modifications of the load lock chamber RL shown in FIGS. 4 and 5 will be described.

(5-1) First Modification

FIG. 9 is a view of a first modification of the load lock chamber RL. Hereinafter, the first modification of the load lock chamber RL will be described by referring to differences from the load lock chamber RL shown in FIGS. 4 and 5.

As shown in FIG. 9, in the first modification of the load lock chamber RL, the cooling pipe 208 is buried in the bottom part of the chamber 201. A plurality of support pins 220 are provided to support the substrate W instead of the heating plate 203.

In this case, the heating of the chamber 201 is carried out in the upper part of the chamber 201, and the cooling of the chamber 201 is carried out in the lower part of the chamber 201. Therefore, the chamber 201 can efficiently be cooled after being heated.

Note that when the chamber 201 is cooled, the substrate W is preferably placed apart from the bottom of the chamber 201 by the lifting pins 204 so that the temperature of the substrate W is not lowered.

The heating plate 203 is not provided in the modification, but moisture or a residue of the organic solvent on the substrate W can be evaporated by adjusting the position or temperature of the heaters 207.

(5-2) Second Modification

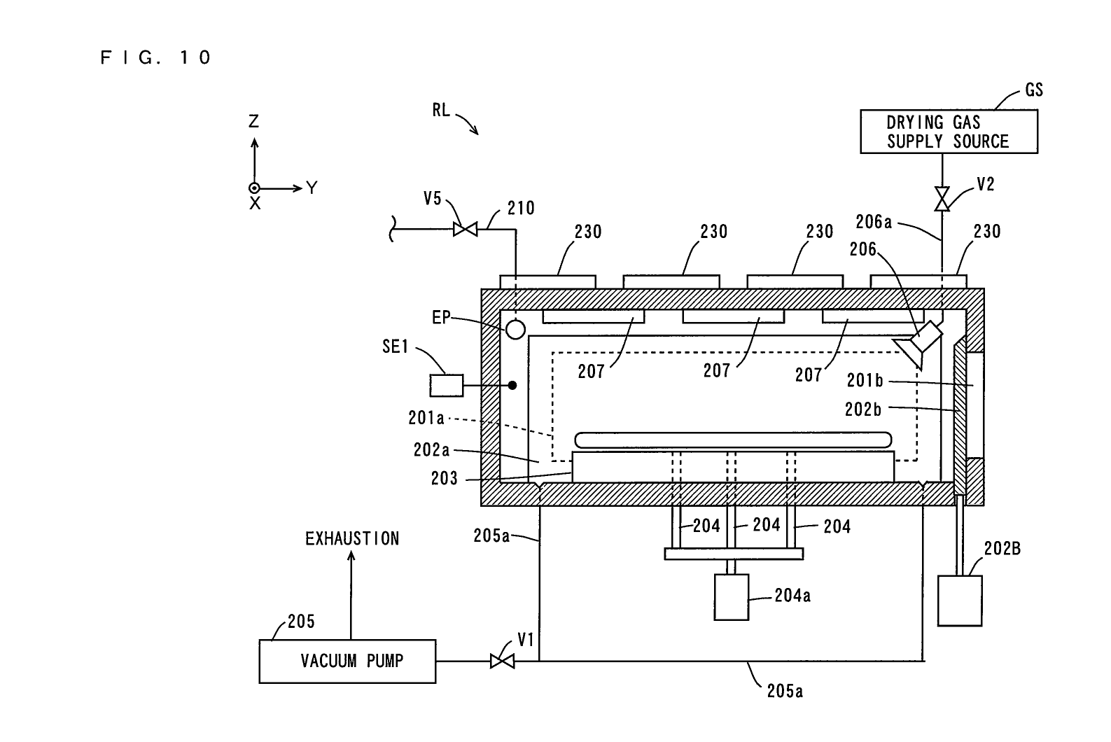

FIG. 10 is a view of a second modification of the load lock chamber RL. Hereinafter, the second modification of the load lock chamber RL will be described by referring to differences from the load lock chamber RL shown in FIGS. 4 and 5.

As shown in FIG. 10, in the second modification of the load lock chamber RL, a Peltier element 230 for cooling is provided instead of the cooling pipes 208 and the refrigerant circulator 208a. In this case, the chamber 201 can be cooled using a simple arrangement, and the load lock chamber RL can be reduced in size and cost.

Note that the Peltier element 230 in FIG. 10 and the cooling pipe 208 and the refrigerant circulator 208a shown in FIG. 5 may be used.

(5-3) Other Modifications

If the evaporated moisture and organic solvent can sufficiently be discharged outside the chamber 201 from the exhaust port EP after the substrate W and the chamber 201 are heated, the drying gas supply nozzle 206 is not necessary.

If the evaporated moisture and organic solvent can sufficiently be discharged outside the chamber 201 by the vacuum pump 205, the drying gas supply nozzle 206 and the exhaust port EP are not necessary.

If the drying gas is supplied into the chamber 201 from the drying gas supply nozzle 206 and the moisture and organic solvent adhering to the substrate W and the chamber 201 can sufficiently be evaporated, the heaters 207 and the heating plate 203 are not necessary.

The chamber 201 starts to be cooled based on the pressure in the chamber 201 detected by the pressure sensor SE1 in the above-described example, but the invention is not limited to the arrangement and the chamber 201 may start to be cooled when a predetermined period elapses.

The rare gas supply nozzle that supplies a rare gas such as helium gas and argon gas into the chamber 201 may be provided, and the atmosphere in the chamber 201 may be replaced by the rare gas before the pressure inside the chamber 201 is reduced. In this case, the rare gas can be discharged output with smaller energy than the case of an atmospheric constituent such as nitrogen, oxygen, and water vapor, and therefore the pressure in the chamber 201 can quickly be reduced.

### (B) Second Embodiment

Now, a substrate processing apparatus 500 according to a second embodiment of the invention will be described. The substrate processing apparatus 500 according to the second embodiment is different from the substrate processing apparatus 500 according to the first embodiment in that the former includes a load lock chamber RLa as will be described in place of the load lock chamber RL.

### (1) Configuration of Load Lock Chamber

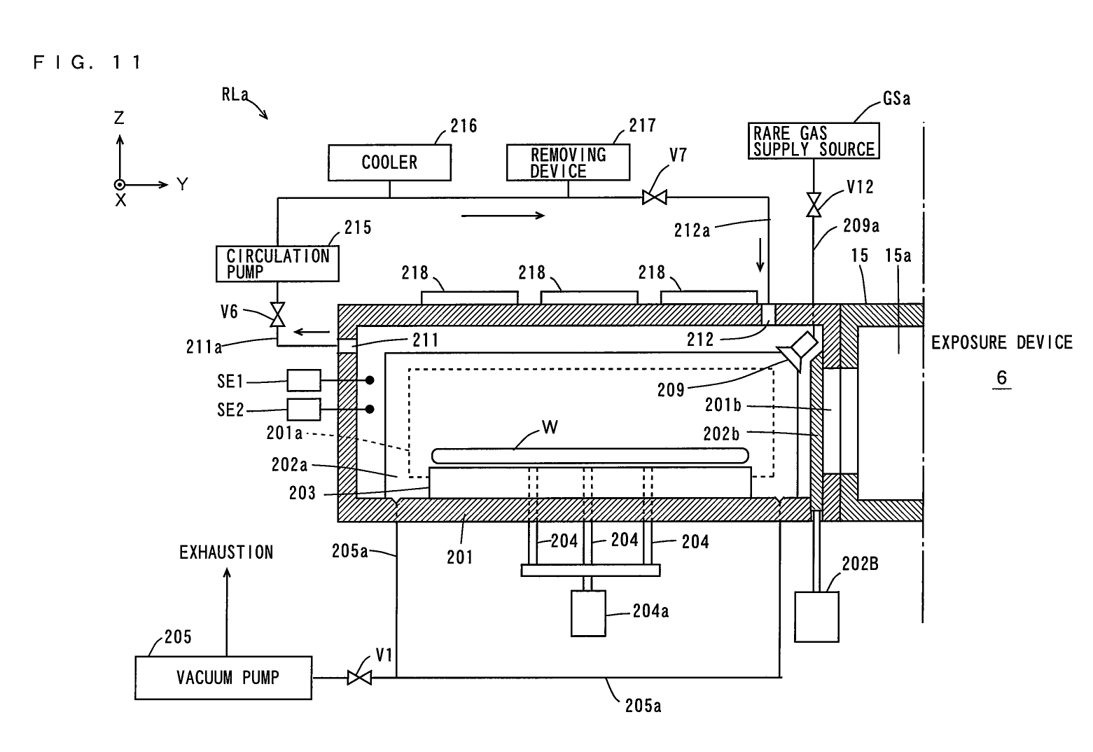

FIG. 11 is a schematic sectional view of the load lock chamber RLa in a YZ plane. As shown in FIG. 11, the load lock chamber RLa includes a chamber 201, shutters 202a and 202b, shutter driving devices 202A and 202B, a heating plate 203, a plurality of lifting pins 204, an lifting pin driving device 204a, a vacuum pump 205, and a pressure sensor SE1 similarly to the load lock chamber RL shown in FIG. 5.

A rare gas supply nozzle 209 is provided above the heating plate 203. The rare gas supply nozzle 209 is connected with a rare gas supply source GSa through a pipe 209a. A control valve V12 is inserted in the pipe 209a. By opening the control valve V12, a rare gas is guided through the pipe 209a from the rare gas supply source GSa to the rare gas supply nozzle 209 and supplied into the chamber 201. According to the embodiment, the rare gas is helium gas.

At the side of the chamber 201, a gas guide outlet 211 is provided. The gas guide outlet 211 is connected with a circulation pipe 211a, in which a valve V6 is inserted. A gas guide inlet 212 is provided in the upper part of the chamber 201. A circulation pipe 212a is connected to the gas guide inlet 212 and a valve V7 is inserted in the circulation pipe 212a. The circulation pipes 211a and 212a are coupled through a circulation pump 215. The circulation pipe 212a is connected with a cooler 216 and a removing device 217.

The circulation pump 215 operates while the valves V6 and V7 are open, so that the atmosphere in the chamber 201 is circulated through the circulation pipes 211a and 212a.

The cooler 216 cools the circulation pipe 212a for example with liquid nitrogen. The cooling temperature is set to a temperature (such as −200° C.) that is lower than the boiling points of atmospheric constituents such as nitrogen (N₂), oxygen (O₂), carbon dioxide (CO₂), and water (H₂O) and higher than the boiling point of helium. The boiling point of nitrogen is −196° C., the boiling point of oxygen is −183° C., the boiling point (sublimation point) of carbon dioxide is −79° C., and the boiling point of water is 100° C. The boiling point of helium is −269° C. The removing device 217 removes components liquefied or solidified in the circulation pipe 212a.

A plurality of heaters 218 used to heat the chamber 201 are attached on the top of the chamber 201. A rare gas concentration sensor SE2 that detects the concentration of helium in the atmosphere is connected to the chamber 201.

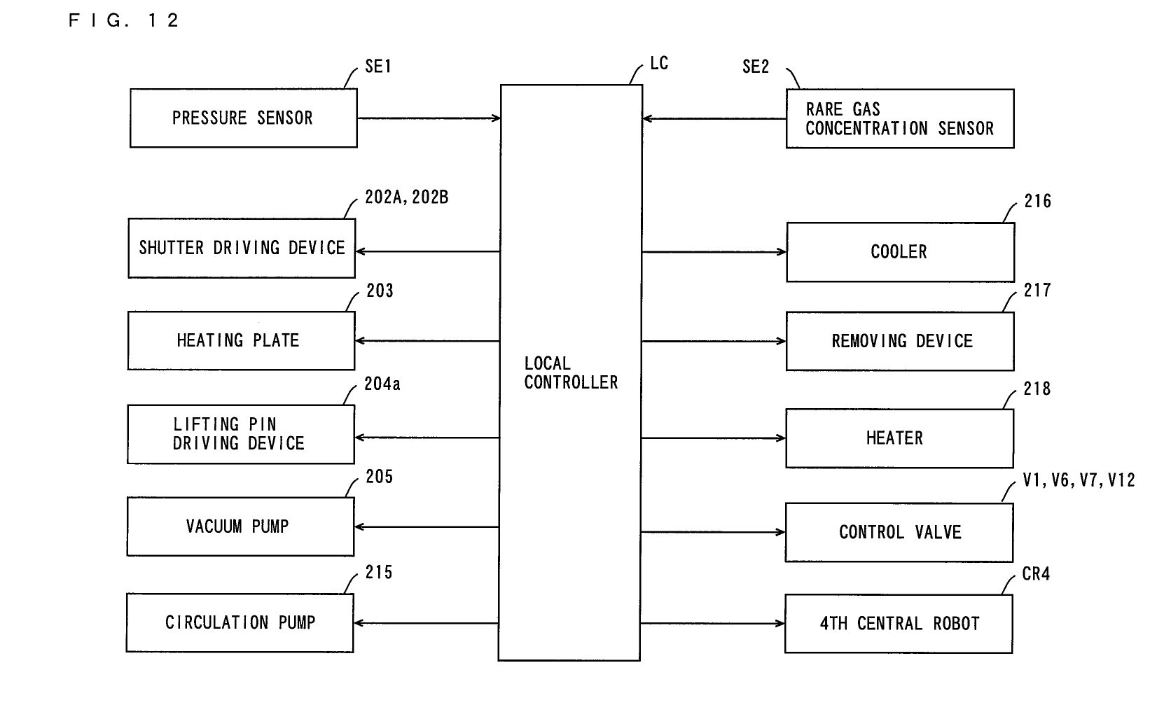

Now, the control system for the load lock chamber RLa will be described. FIG. 12 is a block diagram for use in illustrating the control system for the load lock chamber RLa.

As shown in FIG. 12, the pressure sensor SE1 outputs a detection value for the pressure in the chamber 201 to the local controller LC (see FIG. 1) of the interface block 5, and the rare gas concentration sensor SE2 outputs a detection value for the concentration of helium in the chamber 201 to the local controller LC of the interface block 5. The local controller LC of the interface block 5 outputs a control signal to each of the shutter driving devices 202A and 202B, the heating plate 203, the lifting pin driving device 204a, the vacuum pump 205, the circulation pump 215, the cooler 216, the removing device 217, the heaters 218, the control valves V1, V6, V7, and V12, and the fourth central robot CR4 and controls the operation of these elements.

### (2) Operation of Load Lock Chamber

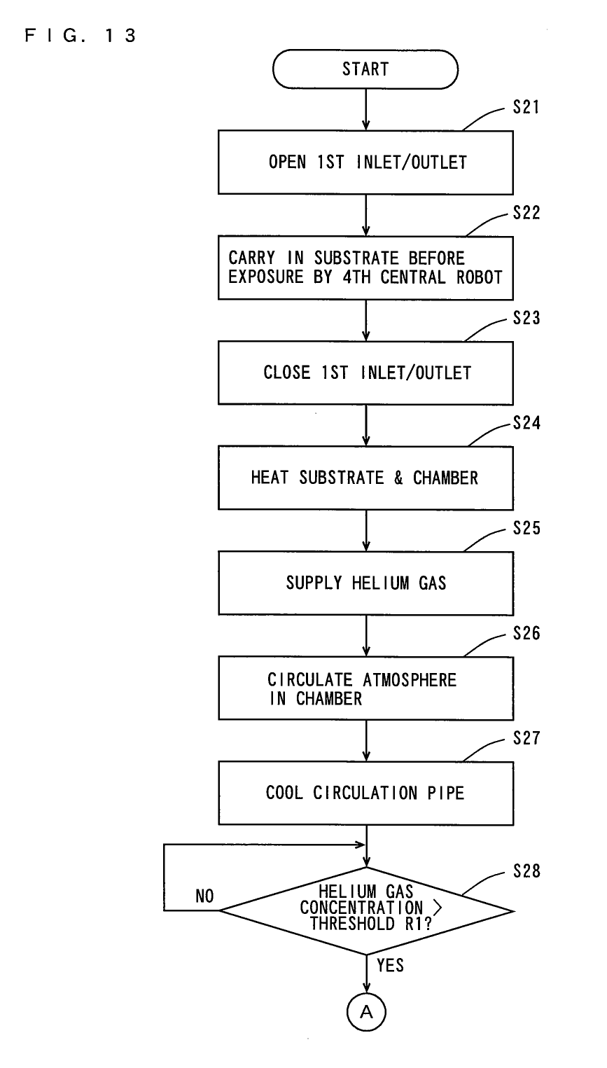

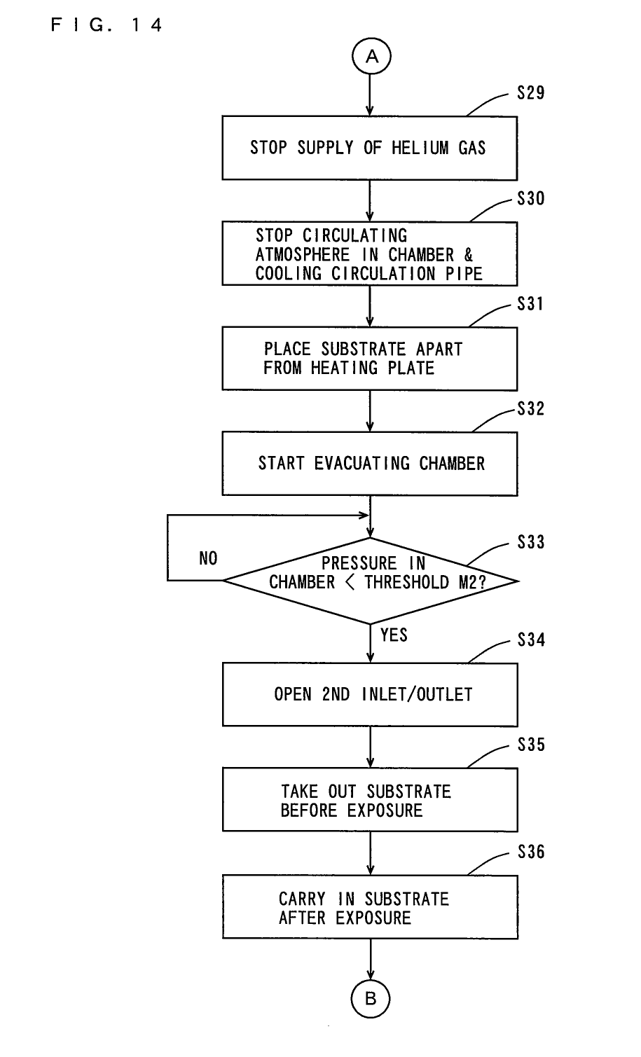

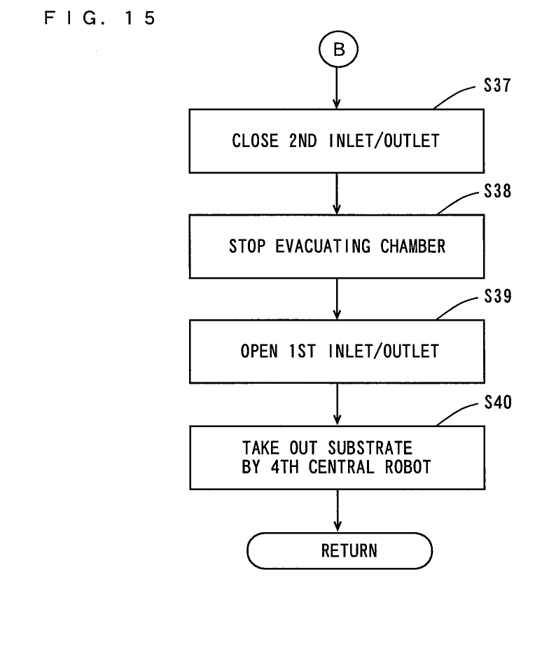

Now, with reference to FIGS. 11 to 15, the operation of the load lock chamber RLa will be described. FIGS. 13 to 15 are flowcharts for use in illustrating the operation of the load lock chamber RLa.

The local controller LC has the shutter 202a lowered by the shutter driving device 202A to open the first inlet/outlet 201a (step S21). Then, the local controller LC has the lifting pins 204 raised by the lifting pin driving device 204a and the substrate W before exposure processing carried into the load lock chamber RLa by the fourth central robot CR4 (FIG. 1) (step S22). The substrate W is then placed on the lifting pins 204.

Then, the local controller LC has the lifting pins 204 lowered by the lifting pin driving device 204a, so that the substrate W is placed on the heating plate 203 and has the shutter 202a raised by the shutter driving device 202A to close the first inlet/outlet 201a (step S23).

The local controller LC has the substrate W heated by the heating plate 203 and the chamber 201 heated by the heaters 218 (step S24). In this way, moisture adhering to the substrate W and the chamber 201 is evaporated. An organic solvent remaining in the organic films (the anti-reflection film and the resist film) on the substrate W and an organic solvent adhering to the chamber 201 are evaporated.

After a prescribed period, the local controller LC stops the heating of the substrate W and the chamber 201. Then, the local controller LC has the control valve 12 opened to start to supply helium gas into the chamber 201 (step S25).

The local controller LC then has the control valves V6 and V7 opened and the circulator 215 activated to circulate the atmosphere in the chamber 201 (step S26). At the same time, the local controller LC has the cooler 216 activated to cool the circulation pipe 212a (step S27).

At the time, atmospheric constituents such as nitrogen, oxygen, carbon dioxide, and water vapor are liquefied or solidified in the circulation pipe 212a and removed by the removing device 217. The moisture and organic solvent evaporated in step S24 described above are also removed in the same manner.

The helium gas supplied into the chamber 201 is kept in the gas state. In this way, the air and the evaporated components in the chamber 201 are replaced by the helium gas, so that the helium gas atmosphere fills the chamber 201.

The local controller LC then determines whether the helium concentration in the atmosphere in the chamber 201 is higher than a predetermined threshold R1 based on a detection value from the rare gas concentration sensor SE2 (step S28).

If the helium concentration is not more than the threshold R1, the local controller LC repeats the determination in step S28. If the helium concentration is higher than the threshold R1, the local controller LC has the control valve V12 closed to stop the supply of the helium gas (step S29). The local controller LC stops the circulator 215 and the cooler 216, so that the circulation of the atmosphere in the chamber 201 and the cooling of the circulation pipe 212a are stopped (step S30) The local controller LC has the control valves V6 and V7 closed.

Then, the local controller LC has the lifting pins 204 raised by the lifting pin driving device 204a, so that the substrate W is placed apart from the heating plate 203 (step S31) and the chamber 201 starts to be evacuated by the vacuum pump 205 (step S32).

In this way, the substrate W is placed apart from the heating plate 203, and therefore the temperature of the substrate W can be lowered. Since the ventilation between the substrate W and the heating plate 203 is secured, so that moisture remaining between the substrate W and the heating plate 203 if any can surely be removed during the evacuation of the chamber 201.

According to the embodiment, before the chamber 201 is evacuated, the helium gas atmosphere fills the chamber 201, and therefore the degree of vacuum in the chamber 201 can quickly be raised. This is for the following reasons.

Atmospheric constituents such as nitrogen, oxygen, carbon dioxide, and water vapor exit as polyatomic molecules. A rare gas such as helium, on the other hand, exists as monatomic molecules. In a polyatomic molecule, motion in the molecule such as rotation and vibration is generated, while no such motion is generated in a monatomic molecule. Therefore, the rare gas is in a lower energy state than the states of the atmospheric constituents such as nitrogen, oxygen, carbon dioxide, and water vapor.

Furthermore, a rare gas is very stable as a monatomic molecule. Therefore, there is almost no interaction between monatomic molecules. More specifically, the energy of the rare gas is particularly low among monatomic molecules.

Therefore, the energy necessary for exhausting the helium gas from chamber 201 of the helium gas is smaller than the energy necessary for exhausting the air. Consequently, the degree of vacuum in the chamber 201 can quickly be raised.

After the chamber 201 starts to be evacuated by the vacuum pump 205, the local controller LC determines whether the pressure in the chamber 201 is lower than the predetermined threshold M2 (such as 10⁻⁶ Pa) based on a detection value from the pressure sensor SE1 (step S33).

If the pressure in the chamber 201 is not less than the threshold M2, the local controller LC repeats the determination in step S33. If the pressure in the chamber 201 is lower than the threshold M2, the local controller LC has the shutter 202b lowered by the shutter driving device 202B to open the second inlet/outlet 201b (step S34).

In the state, the transport mechanism ER (FIG. 1) of the exposure device 6 takes out the substrate W on the lifting pins 204 from the load lock chamber RLa and carries the substrate into the exposure device 6 (step S35). Then, the substrate W after exposure processing is carried into the load lock chamber RLa from the exposure device 6 by the transport mechanism ER and placed on the lifting pins 204 (step S36).

Then, the local controller LC has the shutter 202b raised by the shutter driving device 202B to close the second inlet/outlet 201b (step S37). The local controller LC then stops the evacuation of the chamber 201 by the vacuum pump 205 (step S38).

Thereafter, the local controller LC has the shutter 202a lowered by the shutter driving device 202A to open the first inlet/outlet 201a (step S39). In this way, the inside of the chamber 201 is released to atmospheric pressure. In the state, the local controller LC has the substrate W after exposure processing taken out from the load lock chamber RLa by the fourth central robot CR4 (step S40). Then, the operation in steps S21 to S40 is repeated in the load lock chamber RLa.

### (3) Effects of Second Embodiment

According to the second embodiment, the helium gas atmosphere fills the chamber 201 before the pressure in the chamber 201 is reduced. In this way, the energy necessary for evacuating the chamber 201 can be reduced. Therefore, the degree of vacuum in the chamber 201 can quickly be raised. Consequently, the substrate W can quickly be transported between the substrate processing apparatus 500 and the exposure device 6, which can improve the throughput.

According to the embodiment, when the helium gas is supplied into the chamber 201, the atmosphere in the chamber 201 is circulated while the atmospheric constituents in the atmosphere can selectively be liquefied or solidified for removal. In this way, the consumption of the helium gas can be reduced, while the chamber 201 can efficiently be filled with the helium gas atmosphere.

According to the embodiment, before the pressure in the chamber 201 is reduced, the substrate W is heated by the heating plate 203, so that moisture adhering to the substrate W and an organic solvent in the organic films on the substrate W are evaporated.

In this way, when the pressure in the chamber 201 is reduced, the moisture and organic solvent adhering to the substrate W can be prevented from being solidified because of adiabatic expansion. Therefore, the degree of vacuum in the chamber 201 can be prevented from being lowered by the solidified moisture and organic solvent that are gradually sublimated. Consequently, the degree of vacuum in the chamber 201 can quickly be raised.

According to the embodiment, before the pressure in the chamber 201 is reduced, the chamber 201 is heated by the heaters 218, and the moisture and organic solvent adhering to the chamber 201 are evaporated.

In this way, when the pressure in the chamber 201 is reduced, the moisture and organic solvent adhering to the chamber 201 can be prevented from being solidified because of adiabatic expansion. In this way, the degree of vacuum in the chamber 201 can be prevented from being lowered by solidified moisture and organic solvent that are gradually sublimated. Therefore, the degree of vacuum in the chamber 201 can quickly be raised.

Furthermore, according to the embodiment, the evaporated moisture and organic solvent are liquefied or solidified in the circulation pipe 212a for removal, so that the degree of vacuum can surely be prevented from being lowered in the chamber 201 because of the solidified moisture and organic solvent.

### (4) Modification of Load Lock Chamber

(4-1)

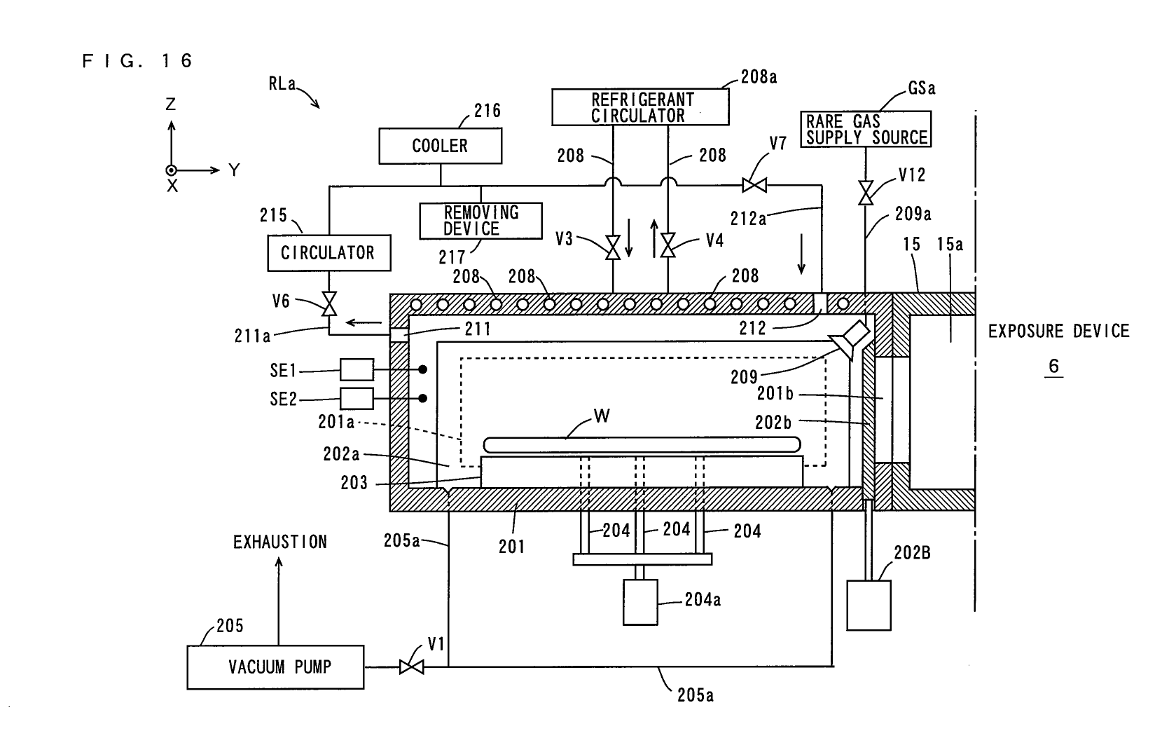

Now, a modification of the load lock chamber RLa will be described. FIG. 16 is a view of a modification of the load lock chamber RLa. Hereinafter, the modification of the load lock chamber RLa will be described by referring to differences between the modification and the load lock chamber RLa shown in FIG. 11.

As shown in FIG. 16, the cooling pipes 208 shown in FIG. 5 are buried in the upper part of the chamber 201. One and the other ends of the cooling pipe 208 are connected with the refrigerant circulator 208a. Control valves V3 and V4 are inserted in the cooling pipe 208.

By opening the control valves V3 and V4, a refrigerant is circulated through the cooling pipes 208 by the refrigerant circulator 208a. In this way, the chamber 201 is cooled. Examples of the refrigerant may include cooling water, liquid nitrogen, liquid helium, nitrogen gas, and helium gas.

In the load lock chamber RLa shown in FIG. 16, when the pressure in the chamber 201 is reduced, the chamber 201 continues to be cooled during the period between when the pressure in the chamber 201 becomes lower than a prescribed value (such as 10⁻³ Pa) and immediately before the inside of the chamber 201 is released to atmospheric pressure.

In this way, when the pressure in the chamber 201 is lower than the prescribed value, almost no airflow exists in the chamber 201. Therefore, molecules remaining in the chamber 201 (including the monatomic molecules of the helium gas) makes substantially no motion but thermal motion.

Since the chamber 201 is cooled in the state, the energy of the thermal motion of the molecules is reduced in the vicinity of the surface of the chamber 201. Therefore, the motion of the molecules substantially stops and the molecules adhere to the inner wall of the chamber 201. Consequently, the degree of vacuum in the chamber 201 can quickly be raised.

The cooling pipe 208 is provided in the upper part of the chamber 201, so that the chamber 201 can be cooled without being affected by the heat from the heating plate 203. Therefore, the chamber 201 can efficiently be cooled.

Note that any other cooling mechanism such as the Peltier element 230 shown in FIG. 10 can be provided instead of the cooling pipe 208 and the refrigerant circulator 208a. Alternatively, a plurality of such cooling mechanisms can be combined.

(4-2) Other Modifications

In any of the above examples, the atmosphere in the chamber 201 is circulated during the supply of the helium gas into the chamber 201 while the atmospheric constituents or the like in the atmosphere are selectively liquefied or solidified for removal, so that the helium gas atmosphere fills the chamber 201, but the helium gas atmosphere may be formed by any other methods.

For example, while the helium gas is supplied into the chamber 201, the chamber 201 may be evacuated using the vacuum pump 205, so that the helium gas atmosphere may be formed in the chamber 201.

Alternatively, while the chamber 201 is sealed, the pressure reduction in the chamber 201 and the supply of helium gas may alternately be repeated multiple times, so that the helium concentration in the chamber 201 may gradually be raised and the helium atmosphere may be formed. Note that in any of these cases, the gas guide outlet 211, the gas guide inlet 212, the circulator 215, the cooler 216, the removing device 217, and the circulation pipes 211a and 212a are not necessary.

Any of the methods of forming the helium gas atmosphere in the above described examples and these methods may be combined. For example, the atmospheric constituents or the like in the atmosphere may be liquefied or solidified and removed while the pressure reduction in the chamber 201 and the supply of the rare gas into the chamber 201 can be carried out simultaneously or alternately, so that the helium gas atmosphere in the chamber 201 may be formed.

In the above-described examples, the helium gas atmosphere is formed in the chamber 201 but the invention is not limited to this and the chamber 201 may be filled with any other rare gas atmosphere such as of neon (Ne), argon (Ar), krypton (Kr), xenon (Xe), and radon (Rn). Also in this case, the energy necessary for evacuating the chamber 201 can be reduced. Therefore, the degree of vacuum in the chamber 201 can quickly be raised.

Note that if a rare gas such as argon (Ar) having a boiling point higher than an atmospheric constituent such as nitrogen is used, the method of carrying out the pressure reduction in the chamber 201 and the supply of the rare gas into the chamber 201 simultaneously or alternately is preferably applied as the method of forming a rare gas atmosphere rather than the method of liquefying and solidifying an atmospheric constituent in the atmosphere for removal.

### (C) Other Embodiments

In the above-described embodiments, the substrate W is processed in a high vacuum state in the exposure device 6 but the substrate W may be processed in a high vacuum state in any of the coating processing group 20, the coating processing group 30, the development processing group 40, and the edge exposure unit EEW in the substrate processing apparatus 500. Alternatively, any other processing unit that carries out processing to the substrate W in a high vacuum state may be provided in the substrate processing apparatus 500.

In this case, a load lock chamber is provided adjacent to the processing unit in a high vacuum state, and the load lock chamber temporarily stores the substrate W when the substrate W is carried into the processing unit in the high vacuum state. In the state, the load lock chamber is brought to a high vacuum state.

### (D) Correspondences Between Elements in Claims and Elements in Embodiments

In the following paragraphs, non-limiting examples of correspondences between various elements recited in the claims below and those described above with respect to various preferred embodiments of the present invention are explained.

In the above-described embodiments, the exposure device 6 is an example of the reduced pressure processing device, the load lock chamber RL is an example of the load lock device in claims 1 to 13, the load lock chamber RLa is an example of the load lock device in claims 14 to 25, the chamber 201 is an example of the housing, and the vacuum pump 205 is an example of the pressure reducing device.

The cooling pipe 208, the refrigerant circulator 208a or the Peltier element 230 is an example of the cooler in claim 1 to 13, the cooling pipe 208 and the refrigerant circulator 208a are an example of the refrigerant supplier, the heater 207 is an example of the housing heater in claim 6, the heating plate 203 is an example of the substrate heater in claim 7, the drying gas supply nozzle 206 is an example of the drying gas supplier, the pressure sensor SE1 is an example of the pressure detector, and the local controller LC of the interface block 5 is an example of the control unit.

The rare gas supply nozzle 209, the cooler 216, or the vacuum pump 205 is an example of the atmosphere replacing device, the rare gas supply nozzle 209 is an example of the rare gas supplier, the cooler 216 is an example of the cooler, the vacuum pump 205 is an example of the exhaust unit, the heater 218 is an example of the housing heater in claim 19, the cooling pipe 208 and the refrigerant circulator 208a are an example of the housing cooler.

The indexer block 1, the anti-reflection film processing block 2, the resist film processing block 3, and the development processing block 4 are an example of the normal pressure processing unit, the interface block 5 is an example of the interface, the substrate processing apparatus 500 and the exposure device 6 are an example of the substrate processing system.

Various other elements having arrangements or functions as recited in the claims may be employed as the elements in the claims.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A load lock device used to carry in or take out a substrate to or from a reduced pressure processing device that carries out processing to the substrate at a pressure lower than atmospheric pressure, comprising:
a housing that can accommodate a substrate and forms a sealed space;
pressure reducing device for reducing pressure in said housing; and
cooler for cooling said housing when said pressure reducing device reduces the pressure in said housing.

2. The load lock device according to claim 1, wherein said cooler includes refrigerant supplier for cooling said housing using a refrigerant.

3. The load lock device according to claim 2, wherein said refrigerant is liquid or gaseous nitrogen.

4. The load lock device according to claim 2, wherein said refrigerant is liquid or gaseous helium.

5. The load lock device according to claim 1, wherein said cooler includes a Peltier element for cooling.

6. The load lock device according to claim 1, further comprising housing heater for heating said housing.

7. The load lock device according to claim 1, further comprising substrate heater for heating a substrate accommodated in said housing.

8. The load lock device according to claim 1, further comprising drying gas supplier for supplying a drying gas into said housing.

9. The load lock device according to claim 1, further comprising:
a pressure detector that detects the pressure in said housing; and
a control unit that starts cooling of said housing by said cooler if the pressure detected by said pressure detector is lower than a predetermined value.

10. A substrate processing apparatus provided adjacent to a reduced pressure processing device that carries out processing to a substrate at a pressure lower than atmospheric pressure, comprising:
a normal pressure processing unit that carries out processing to a substrate at atmospheric pressure; and
an interface used to receive and transfer the substrate between said normal pressure processing unit and said reduced pressure processing device,
said interface comprising a load lock device used to carry in or take out a substrate to or from said reduced pressure processing device,
said load lock device comprising:
a housing that can accommodate a substrate and forms a sealed space;
pressure reducing device for reducing pressure in said housing; and
cooler for cooling said housing when said pressure reducing device reduces the pressure in said housing.

11. A substrate processing system, comprising:
a reduced pressure processing device that carries out processing to a substrate at a pressure lower than atmospheric pressure; and
a load lock device used to carry in or take out a substrate to or from said reduced pressure processing device,
said load lock device comprising:
a housing that can accommodate a substrate and forms a sealed space;
pressure reducing device for reducing pressure in said housing; and
cooler for cooling said housing when said pressure reducing device reduces the pressure in said housing.

12. The substrate processing system according to claim 11, further comprising an interface that transports a substrate to said reduced pressure processing device, wherein said load lock device is provided at said interface.

13. The substrate processing system according to claim 12, further comprising a normal pressure processing unit that carries out processing to a substrate at atmospheric pressure, wherein said interface receives and transfers a substrate between said normal pressure processing unit and said reduced pressure processing device.

14. A load lock device used to carry in or take out a substrate to or from a reduced pressure processing device that carries out processing to a substrate at a pressure lower than atmospheric pressure, comprising:
a housing that can accommodate a substrate and forms a sealed space;
pressure reducing device for reducing pressure in said housing; and
atmosphere replacing device for replacing the atmosphere in said housing with a rare gas before said pressure reducing device reduces the pressure in said housing.

15. The load lock device according to claim 14, wherein said atmosphere replacing device includes rare gas supplier for supplying the rare gas into said housing.

16. The load lock device according to claim 15, wherein said atmosphere replacing device further includes cooler for liquefying or solidifying a constituent in the atmosphere in said housing excluding the rare gas.

17. The load lock device according to claim 16, wherein said rare gas is helium gas.

18. The load lock device according to claim 15, wherein the atmosphere replacing device comprises exhaust unit for exhausting the atmosphere from said housing.

19. The load lock device according to claim 14, further comprising housing heater for heating said housing.

20. The load lock device according to claim 14, further comprising substrate heater for heating a substrate accommodated in said housing.

21. The load lock device according to claim 14, further comprising housing cooler for cooling said housing when said pressure reducing device reduces the pressure in said housing.

22. A substrate processing apparatus provided adjacent to a reduced pressure processing device that carries out processing to a substrate at a pressure lower than atmospheric pressure, comprising:
a normal pressure processing unit that carries out processing to the substrate at atmospheric pressure; and
an interface used to receive and transfer the substrate between said normal pressure processing unit and said reduced pressure processing device,
said interface comprising a load lock device used to carry in or take out a substrate to or from said reduced pressure processing device,
said load lock device comprising:
a housing that can accommodate a substrate and forms a sealed space;
pressure reducing device for reducing pressure in said housing; and
atmosphere replacing device for replacing the atmosphere in said housing with a rare gas before said pressure reducing device reduces the pressure in said housing.

23. A substrate processing system, comprising:
a reduced pressure processing device that carries out processing to a substrate at a pressure lower than atmospheric pressure; and
a load lock device used to carry in or take out a substrate to or from said reduced pressure processing device,
said load lock device comprising:
a housing that can accommodate a substrate and forms a sealed space;
pressure reducing device for reducing pressure in said housing; and
atmosphere replacing device for replacing the atmosphere in said housing with a rare gas before said pressure reducing device reduces the pressure in said housing.

24. The substrate processing system according to claim 23, further comprising an interface that transports a substrate to said reduced pressure processing device, wherein said load lock device is provided at said interface.

25. The substrate processing system according to claim 24, further comprising a normal pressure processing unit that carries out processing to a substrate at atmospheric pressure, wherein said interface receives and transfers the substrate between said normal pressure processing unit and said reduced pressure processing device.
